(19) United States
(12) Patent Application Publication
(10) Pub. No.: US 2026/0157038 A1
(43) Pub. Date: Jun. 4, 2026

(54) DISPLAY DEVICE

(71) Applicant: Samsung Display Co., Ltd., Yongin-si (KR)

(72) Inventors: Seung Jun LEE, Yongin-si (KR); Tae Ho KIM, Yongin-si (KR); Gun Hee KIM, Yongin-si (KR); Jae Woo LEE, Yongin-si (KR); Joo Hee JEON, Yongin-si (KR); Sun Young JUNG, Yongin-si (KR)

(21) Appl. No.: 19/338,975

(22) Filed: Sep. 24, 2025

(30) Foreign Application Priority Data
Dec. 3, 2024 (KR) 10-2024-0177059

(51) Int. Cl. H10K 59/121

(52) U.S. Cl. CPC H10K 59/1213

(57) ABSTRACT

A display device includes, a substrate, a circuit layer on the substrate, and a light emitting element layer on the circuit layer and including light emitting elements, wherein the circuit layer includes, a light emitting pixel driver electrically connected to the light emitting elements, a first active layer, a first gate conductive layer on the first active layer, a second gate conductive layer on the first gate conductive layer, a second active layer on the second gate conductive layer, and a third gate conductive layer on the second active layer, and wherein the light emitting pixel driver includes: a first capacitor including capacitor electrodes respectively located in the second gate conductive layer and the third gate conductive layer, and a second capacitor including capacitor electrodes respectively located in the first active layer, the first gate conductive layer, and the second gate conductive layer.

### CROSS-REFERENCE TO RELATED APPLICATION

This application claims priority to and the benefit of Korean Patent Application No. 10-2024-0177059, filed on Dec. 3, 2024, in the Korean Intellectual Property Office, the entire disclosure of which is incorporated by reference herein.

### BACKGROUND

### 1. Field

The present disclosure relates to a display device.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

The display device may be a flat panel display device such as a liquid crystal display device, a field emission display device, or a light emitting display device. Here, the light emitting display device may include an organic light emitting display device including an organic light emitting device, an inorganic light emitting display device including an inorganic light emitting device such as an inorganic semiconductor, and a micro or nano light emitting display device including a micro or nano light emitting device.

One surface of the display device may be a display surface including a display area where an image is displayed and a non-display area surrounding the display area. Light emitting areas that emit light with respective luminance and color may be arranged in the display area.

### SUMMARY

Aspects and features of embodiments of the present disclosure provide a display device that is suitable to increase a resolution by improving the degree of integration of light emitting pixel drivers.

Aspects and features of embodiments of the present disclosure also provide a display device having increased capacitance of a capacitor.

However, aspects and features of embodiments of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including, a substrate, a circuit layer on the substrate, and a light emitting element layer on the circuit layer and including light emitting elements, wherein the circuit layer includes, a light emitting pixel driver electrically connected to the light emitting elements, a first active layer, a first gate conductive layer on the first active layer, a second gate conductive layer on the first gate conductive layer, a second active layer on the second gate conductive layer, and a third gate conductive layer on the second active layer, and wherein the light emitting pixel driver includes, a first capacitor including capacitor electrodes respectively located in the second gate conductive layer and the third gate conductive layer, and a second capacitor including capacitor electrodes respectively located in the first active layer, the first gate conductive layer, and the second gate conductive layer.

In one or more embodiments, the circuit layer further includes an interlayer insulating layer between the second gate conductive layer and the second active layer, and the interlayer insulating layer exposes at least a portion of an upper surface of the capacitor electrode of the first capacitor, the capacitor electrode of the first capacitor being in the second gate conductive layer.

In one or more embodiments, the interlayer insulating layer is not located between the capacitor electrodes of the first capacitor.

In one or more embodiments, the interlayer insulating layer does not overlap the capacitor electrode of the first capacitor, the capacitor electrode of the first capacitor being in the third gate conductive layer, in a thickness direction of the substrate.

In one or more embodiments, the circuit layer further includes a gate insulating layer between the second active layer and the third gate conductive layer, and at least a portion of the gate insulating layer is in contact with the upper surface of the capacitor electrode of the first capacitor, the capacitor electrode of the first capacitor being in the second gate conductive layer.

In one or more embodiments, a thickness of the gate insulating layer is smaller than a thickness of the interlayer insulating layer.

In one or more embodiments, the light emitting pixel driver further includes a first transistor on the interlayer insulating layer, and the interlayer insulating layer is located between the first transistor and the capacitor electrode of the second capacitor, the capacitor electrode of the second capacitor being in the second gate conductive layer.

In one or more embodiments, the interlayer insulating layer is located only below the first transistor and is not located below the capacitor electrode of the first capacitor, the capacitor electrode of the first capacitor being in the third gate conductive layer.

In one or more embodiments, the interlayer insulating layer was formed by using a pattern of the second active layer as a mask.

In one or more embodiments, the first active layer includes a silicon semiconductor material, and the second active layer includes an oxide semiconductor material.

In one or more embodiments, the first active layer includes a p-type semiconductor, and the second active layer includes an n-type semiconductor.

In one or more embodiments, the above light emitting pixel driver includes a first light emitting pixel driver and a second light emitting pixel driver that are located in parallel, and the first light emitting pixel driver and the second light emitting pixel driver have a left-right symmetrical structure with respect to a boundary therebetween.

In one or more embodiments, the display device may further comprise, a data line configured to transmit a data signal to the first light emitting pixel driver and the second light emitting pixel driver, and a transmission auxiliary line electrically connected to the first light emitting pixel driver and the second light emitting pixel driver, wherein the transmission auxiliary line is configured to be connected to the data line and transmit the data signal.

According to one or more embodiments of the present disclosure, there is provided a display device including, a substrate, a circuit layer on the substrate, and a light emitting element layer on the circuit layer and including light emitting elements, wherein the circuit layer includes, a light emitting pixel driver electrically connected to the light emitting elements and including a first transistor, a second transistor, a first capacitor, and a second capacitor, and an interlayer insulating layer located between the first transistor and the second transistor, wherein the second capacitor is located below the interlayer insulating layer, wherein the first capacitor includes a first capacitor electrode and a second capacitor electrode on the first capacitor electrode, and wherein a distance between an upper surface of the interlayer insulating layer and an upper surface of the substrate is greater than a distance between a lower surface of the second capacitor electrode of the first capacitor and the upper surface of the substrate.

In one or more embodiments, the second capacitor electrode of the first capacitor does not overlap the interlayer insulating layer in a thickness direction of the substrate.

In one or more embodiments, the second capacitor electrode of the first capacitor is located above the second capacitor.

In one or more embodiments, the interlayer insulating layer overlaps the first transistor in a thickness direction of the substrate.

In one or more embodiments, the first transistor includes an oxide semiconductor, and the second transistor includes a silicon semiconductor.

In one or more embodiments, the circuit layer further includes a gate insulating layer located between the first capacitor electrode and the second capacitor electrode of the first capacitor, and the first capacitor electrode is in contact with the gate insulating layer.

In one or more embodiments, the gate insulating layer is in contact with one electrode of the second capacitor.

The display device according to one or more embodiments of the present disclosure may be suitable to increase the resolution by improving the integration of the light emitting pixel drivers.

In the display device according to one or more embodiments of the present disclosure, the capacitance of the capacitor may be increased.

However, the effects, aspects, and features of the embodiments of the present disclosure are not restricted to the one set forth herein. The above and other effects, aspects, and features of the embodiments of the present disclosure will become more apparent to one of daily skill in the art to which the embodiments pertain by referencing the claims.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view illustrating a display device according to one or more embodiments;

FIG. 2 is a plan view illustrating the display device of FIG. 1;

FIG. 3 is a cross-sectional view taken along the line A-A′ of FIG. 2;

FIG. 4 is a layout view illustrating a portion B of FIG. 2.

FIG. 5 is an equivalent circuit diagram illustrating a light emitting pixel driver of FIG. 4 according to one or more embodiments;

FIG. 6 is a plan view illustrating a display panel and a display driving circuit according to one or more embodiments;

FIG. 7 is a layout view illustrating a circuit layer of a portion C of FIG. 6;

FIG. 8 is a layout view illustrating a circuit layer of a portion D of FIG. 6;

FIG. 9 is a cross-sectional view illustrating a first transistor, a third transistor, a sixth transistor, a first capacitor, a second capacitor, and a light emitting element of FIG. 5;

FIG. 10 is an enlarged cross-sectional view of a portion E of FIG. 9;

FIG. 11 is a layout view illustrating a circuit layer of a portion F of FIG. 8;

FIG. 12 is a layout view illustrating a first active layer and a doped electrode of a circuit layer according to one or more embodiments;

FIG. 13 is a layout view illustrating a first gate conductive layer of a circuit layer according to one or more embodiments;

FIG. 14 is a layout view illustrating a second gate conductive layer of a circuit layer according to one or more embodiments;

FIG. 15 is a layout view illustrating a second active layer of a circuit layer according to one or more embodiments;

FIG. 16 is a layout view illustrating a third gate conductive layer of a circuit layer according to one or more embodiments;

FIG. 17 is a layout view illustrating a first contact hole group, a second contact hole group, and a first source-drain conductive layer of a circuit layer according to one or more embodiments;

FIG. 18 is a layout view illustrating a first via hole group and a second source-drain conductive layer of a circuit layer according to one or more embodiments;

FIG. 19 is a layout view illustrating a second via hole group, an anode electrode, and a pixel defining layer of a circuit layer according to one or more embodiments;

FIG. 20 is a layout view illustrating a first capacitor area;

FIG. 21 is a layout view illustrating a second capacitor area; and

FIG. 22 is a layout view illustrating a first interlayer insulating layer and a second active layer of a circuit layer according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in detail with reference to the accompanying drawings.

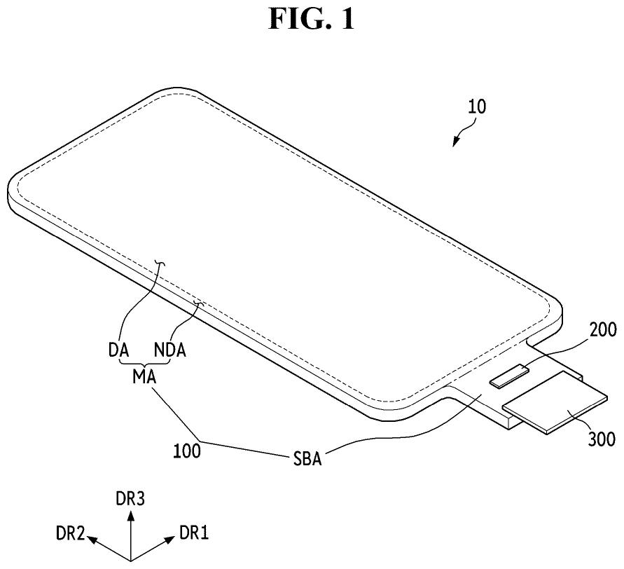

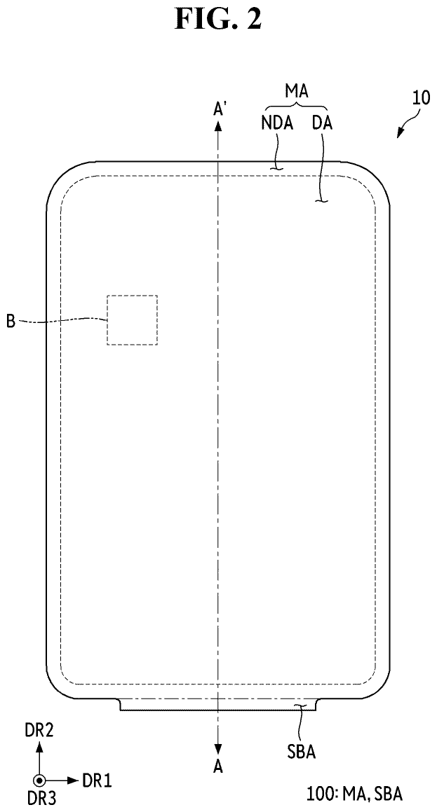

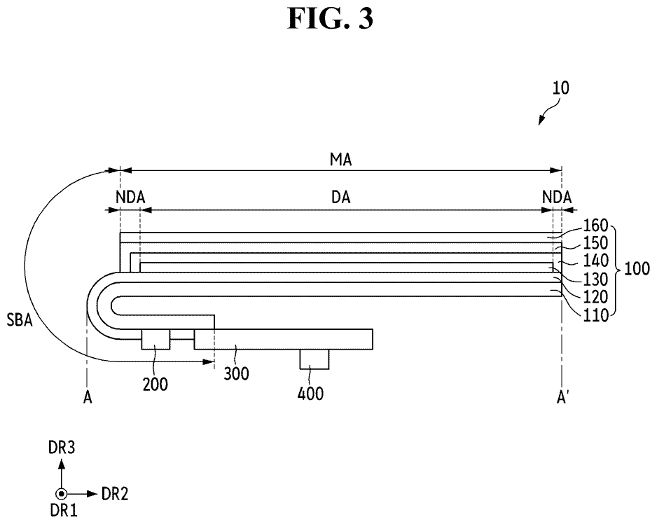

FIG. 1 is a perspective view illustrating a display device according to one or more embodiments. FIG. 2 is a plan view illustrating the display device of FIG. 1. FIG. 3 is a cross-sectional view taken along the line A-A′ of FIG. 2.

FIG. 1 illustrates a state in which a sub-area SBA of a display device 10 is unfolded, and FIGS. 2 and 3 illustrate a state in which the sub-area SBA of the display device 10 is bent.

Referring to FIGS. 1-3, a display device 10 is a device that displays a moving image and/or a still image, and may be used as a display screen of each of various products such as televisions, laptop computers, monitors, billboards, and/or Internet of Things (IoT) as well as portable electronic devices such as mobile phones, smartphones, tablet personal computers (PCs), smartwatches, watch phones, mobile communication terminals, electronic organizers, electronic books, portable multimedia players (PMPs), navigation devices, and/or ultra mobile PCs (UMPCs).

The display device 10 may include a display panel 100. The display panel 100 may be a light emitting display panel such as an organic light emitting display panel using an organic light emitting diode (OLED), a light emitting display panel such as a quantum dot light emitting display panel including a quantum dot light emitting layer, an inorganic light emitting display panel including an inorganic semiconductor, and a micro or nano light emitting display panel using a micro or nano light emitting diode (LED). Hereinafter, the display panel 100 is mainly described as an organic light emitting display panel, but the present disclosure is not limited thereto.

The display panel 100 may be formed to be flat, but is not limited thereto. For example, the display panel 100 may include curved surface portions formed at left and right distal ends thereof and having a constant curvature or a variable curvature. In addition, the display panel 100 may be flexibly formed to be curved, bent, folded, and/or rolled.

The display panel 100 may include a main area MA corresponding to a display surface of the display device 10 and a sub-area SBA protruding from one side of the main area MA.

The main area MA may include a display area DA disposed at most of the center and a non-display area NDA disposed around the display area DA. The display area DA may be formed in a rectangular plane having a short side in a first direction DR1 and a long side in a second direction DR2. A corner where the short side in the first direction DR1 and the long side in the second direction DR2 meet may be rounded to have a suitable curvature (e.g., a predetermined curvature) or may be formed at a right angle. However, the planar shape of the display area DA is not limited to the quadrangular shape, and the display area DA may be formed in other polygonal, circular, and/or oval shapes. The non-display area NDA may be disposed at an edge of the main area MA to be around (e.g., to surround) the display area DA along an edge or a periphery of the display area DA.

In the illustrated drawings, the first direction DR1 and the second direction DR2 are horizontal directions and intersect each other. For example, the first direction DR1 and the second direction DR2 may be orthogonal to each other. In addition, a third direction DR3 may be a vertical direction intersecting the first direction DR1 and the second direction DR2, for example, orthogonal to the first direction DR1 and the second direction DR2. Unless otherwise defined, in the present specification, directions indicated by arrows in the first to third directions DR1, DR2, and DR3 may be referred to as one side, and the opposite directions thereof may be referred to as the other side. In addition, in the present specification, “on”, “upper side”, “upper portion”, “top”, and “upper surface” refer to a direction in which an arrow in the drawing is directed in a third direction DR3 based on the drawing, and “below”, “lower side”, “lower portion”, “bottom”, and “lower surface” refer to a direction opposite to the direction in which the arrow in the third direction DR3 is directed based on the drawing.

The sub-area SBA may be an area extending in the second direction DR2 from a portion of one side of the main area MA extending in the first direction DR1. The sub-area SBA may include a bending area that is deformed into a bent shape.

As illustrated in FIG. 3, the sub-area SBA may include a bending area that is deformed into a bent shape, a first sub-area disposed between one side of the main area MA and one side of the bending area, and a second sub-area extending from the other side of the bending area. When the bending area is deformed into the bent shape, the second sub-area may be disposed on a rear surface of the display device 10 and may overlap the main area MA. A display driving circuit 200 provided as an integrated circuit chip (IC) may be mounted in the second sub-area. A circuit board 300 may be bonded to one side of the second sub-area. A touch driving circuit 400 provided as an integrated circuit chip (IC) may be mounted on the circuit board 300.

As illustrated in FIG. 3, the display panel 100 of the display device 10 according to one or more embodiments may include a substrate 110, a circuit layer 120, an element layer 130, a sealing layer 140, a touch sensor layer 150, and a polarizing layer 160.

The substrate 110 may be made of an insulating material such as a polymer resin. For example, the substrate 110 may be made of polyimide. The substrate 110 may be a flexible substrate that may be bent, folded, and/or rolled. Alternatively, the substrate 110 may be made of an insulating material such as glass.

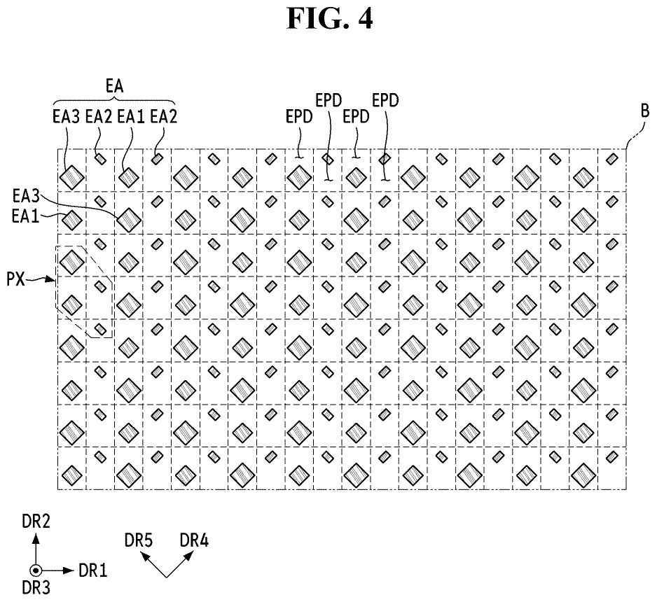

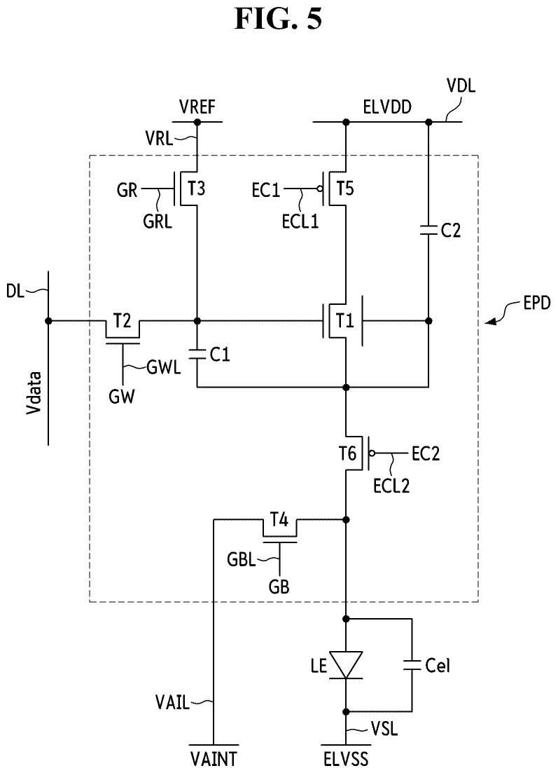

The element layer 130 may include light emitting elements LE (see FIG. 5) respectively disposed in light emitting areas EA (see FIG. 4).

The circuit layer 120 may include light emitting pixel drivers EPD (see FIG. 4) that are electrically connected to the light emitting elements LE (see FIG. 5) of the element layer 130, respectively.

The sealing layer 140 is disposed on the element layer 130 and may have a structure in which at least one organic film is interposed between two or more inorganic films.

The touch sensor layer 150 may include touch electrodes for detecting a signal that varies depending on a touch of a person or object and sensing a point in the main area MA where the touch of the person or object occurred.

The polarizing layer 160 may prevent image visibility from being reduced due to reflection of external light by blocking external light reflected from the touch sensor layer 150, the sealing layer 140, the element layer 130, the circuit layer 120, and interfaces therebetween.

According to one or more embodiments, the display device 10 may further include a display driving circuit 200 provided as an integrated circuit chip (IC) and mounted in the sub-area SBA.

The display driving circuit 200 may supply data signals Vdata (see FIG. 5) to data lines DL (see FIG. 5) of the circuit layer 120.

According to one or more embodiments, the display device 10 may further include a circuit board 300 mounted in the sub-area SBA. The circuit board 300 may be bonded to pads disposed in the sub-area SBA using an anisotropic conductive film and/or the like.

According to one or more embodiments, the display device 10 may further include a touch driving circuit 400 mounted on the circuit board 300. When the touch sensor layer 150 includes capacitive touch electrodes and sensing electrodes, the touch driving circuit 400 may sense a touch based on whether or not a capacitance changes. However, this is merely an example, and the touch sensor layer 150 and touch driving circuit 400 of FIG. 3 may be provided in a touch sensing method other than the capacitive method.

FIG. 4 is a layout view illustrating a portion B of FIG. 2.

Referring to FIG. 4 in addition to FIGS. 1-3, the display area DA of the display device 10 according to one or more embodiments may include light emitting areas EA. In addition, the display area DA may further include a non-light emitting area disposed in a spaced portion between the light emitting areas EA.

The light emitting pixel drivers EPD each corresponding to the light emitting areas EA may be arranged in the display area DA to be parallel to each other in the first direction DR1 and the second direction DR2. The light emitting pixel drivers EPD may be electrically connected to the light emitting elements LE (see FIG. 5) of the element layer 130 each disposed in the light emitting areas EA.

The light emitting areas EA may have a rhombic planar shape or a rectangular planar shape. However, this is merely an example, and the planar shape of the light emitting areas EA according to one or more embodiments is not limited to that illustrated in FIG. 4. That is, the light emitting areas EA may have a polygonal planar shape such as a square, pentagon, or hexagon, or a circular or oval planar shape including curved edges.

The light emitting areas EA may include first light emitting areas EA1 that emit light in a first wavelength band, second light emitting areas EA2 that emit light in a second wavelength band lower than the first wavelength band, and third light emitting areas EA3 that emit light in a third wavelength band lower than the second wavelength band.

As an example, the first wavelength band may correspond to red and may be from about 600 nm to about 750 nm. The second wavelength band may correspond to green and may be from about 480 nm to about 560 nm. The third wavelength band may correspond to blue and may be from about 370 nm to about 460 nm.

The first light emitting areas EA1 and the third light emitting areas EA3 may be alternately arranged along the first direction DR1 or the second direction DR2. The second light emitting areas EA2 may be arranged to be parallel to each other in the first direction DR1 or the second direction DR2. In addition, the second light emitting areas EA2 may be adjacent to the first light emitting areas EA1 and the third light emitting areas EA3 in diagonal directions DR4 and DR5 intersecting the first and second directions DR1 and DR2.

Pixels PX that display each luminance and color may be provided by the first light emitting area EA1, the second light emitting area EA2, and the third light emitting area EA3 adjacent to each other from among the light emitting areas EA. For example, as illustrated in the drawing, one first light emitting area EA1, two second light emitting areas EA2, and one third light emitting area EA3 adjacent to each other may constitute one pixel PX. However, the present disclosure is not limited thereto, and the number of each of the first light emitting areas EA1, the second light emitting areas EA2, and the third light emitting areas EA3 included in one pixel PX may be variously changed.

In other words, the pixels PX may be basic units that display various colors, including white, at a suitable luminance (e.g., a predetermined luminance). Each of the pixels PX may include at least one first light emitting area EA1, at least one second light emitting area EA2, and at least one third light emitting area EA3 adjacent to each other. Accordingly, each of the pixels PX may display various colors through mixing of light emitted from the first, second, and third light emitting areas EA1, EA2, and EA3 adjacent to each other.

FIG. 5 is an equivalent circuit diagram illustrating a light emitting pixel driver of FIG. 4 according to one or more embodiments.

Referring to FIG. 5 in addition to FIGS. 3 and 4, the circuit layer 120 may include a first power line VDL that transmits a first power ELVDD to the light emitting pixel drivers EPD, a second power line VSL that transmits a second power ELVSS to the light emitting elements LE, a reference voltage line VRL that transmits a reference voltage VREF to the light emitting pixel drivers EPD, an initialization voltage line VAIL that transmits an initialization voltage VAINT, and a data line DL that transmits a data signal Vdata to the light emitting pixel drivers EPD.

The light emitting elements LE of the element layer 130 may be electrically connected between the light emitting pixel drivers EPD and the second power line VSL. One of the light emitting elements LE may be electrically connected between one of the light emitting pixel drivers EPD and the second power line VSL.

The second power ELVSS may have a lower voltage level than the first power ELVDD. An anode electrode of the light emitting element LE may be electrically connected to the light emitting pixel driver EPD, and the second power ELVSS having the lower voltage level than the first power ELVDD may be applied to a cathode electrode of the light emitting element LE.

A light emitting capacitor Cel connected in parallel with the light emitting element LE represents a parasitic capacitance between the anode electrode and the cathode electrode of the light emitting element LE.

The circuit layer 120 may include a scan write line GWL that transmits a scan write signal GW, a reset control line GRL that transmits a reset control signal GR, a bias control line GBL that transmits a bias control signal GB, a first emission control line ECL1 that transmits a first emission control signal EC1, and a second emission control line ECL2 that transmits a second emission control signal EC2.

One light emitting pixel driver EPD of the circuit layer 120 may include a first transistor T1 that generates a driving current for driving the light emitting element LE, two or more transistors T2 to T6 electrically connected to the first transistor T1, and one or more capacitors C1 and C2.

A second transistor T2 may be electrically connected between a gate electrode of the first transistor T1 and the data line DL. The second transistor T2 may be turned on by the scan write signal GW of the scan write line GWL. When the second transistor T2 is turned on, the data signal Vdata of the data line DL may be transmitted to the gate electrode of the first transistor T1.

When a voltage difference between the gate electrode of the first transistor T1 and a second electrode (e.g., a source electrode) of the first transistor T1 is equal to or greater than a threshold voltage of the first transistor T1 by the data signal Vdata applied to the gate electrode of the first transistor T1, the first transistor T1 may be turned on. Accordingly, a drain-source current of the first transistor T1 may be generated in a size corresponding to the data signal Vdata.

A third transistor T3 may be electrically connected between the gate electrode of the first transistor T1 and the reference voltage line VRL. The third transistor T3 may be turned on by the reset control signal GR of the reset control line GRL. When the third transistor T3 is turned on, a potential of the gate electrode of the first transistor T1 may be reset to the reference voltage VREF of the reference voltage line VRL.

A fourth transistor T4 may be electrically connected between the light emitting element LE and the initialization voltage line VAIL. The fourth transistor T4 may be turned on by the bias control signal GB of the bias control line GBL. When the fourth transistor T4 is turned on, the potential of the anode electrode of the light emitting element LE may be initialized to the initialization voltage VAINT of the initialization voltage line VAIL.

A fifth transistor T5 may be electrically connected between the first electrode (e.g., the drain electrode) of the first transistor T1 and the first power line VDL. The fifth transistor T5 may be turned on by the first emission control signal EC1 of the first emission control line ECL1. When the fifth transistor T5 is turned on, the first power ELVDD of the first power line VDL may be transmitted to the first electrode of the first transistor T1.

A sixth transistor T6 may be electrically connected between the second electrode (e.g., the source electrode) of the first transistor T1 and the light emitting element LE. The sixth transistor T6 may be turned on by the second emission control signal EC2 of the second emission control line ECL2. When the sixth transistor T6 is turned on, the drain-source current of the first transistor T1 generated in the magnitude corresponding to the data signal Vdata may be transmitted to the light emitting element LE through the sixth transistor T6. As a result, the light emitting element LE may emit light with luminance corresponding to the data signal Vdata.

The first capacitor C1 may be electrically connected between the gate electrode of the first transistor T1 and the second electrode (e.g., the source electrode) of the first transistor T1.

Accordingly, the first capacitor C1 may be charged with the data signal Vdata applied to the gate electrode of the first transistor T1, and due to the voltage charged to the first capacitor C1, the turn-on of the first transistor T1 may be maintained for a suitable period of time (e.g., a predetermined period of time).

The second capacitor C2 may be electrically connected between the second electrode (e.g., the source electrode) of the first transistor T1 and the first power line VDL.

A voltage of the first capacitor C1 may correspond to a potential difference between the gate electrode of the first transistor T1 and the second electrode (e.g., the source electrode) of the first transistor, may be varied by the data signal Vdata, and may be divided by the second capacitor C2. Accordingly, the threshold voltage of the first transistor T1 may be compensated, and a stable operation may be implemented by compensating for fluctuations in the threshold voltage of the first transistor T1.

According to one or more embodiments, the first transistor T1 may include a gate electrode and a gate additional electrode that face both sides of the channel portion. The gate electrode of the first transistor T1 may be electrically connected to the second transistor T2. The gate additional electrode of the first transistor T1 may be electrically connected to the second electrode (e.g., the source electrode) of the first transistor T1.

Accordingly, when the first transistor T1 is turned on by applying the data signal Vdata to the gate electrode of the first transistor T1, another portion of the channel portion of the first transistor T1 adjacent to the gate additional electrode may not be activated compared to a portion of the channel portion of the first transistor T1 adjacent to the gate electrode.

Therefore, because electron mobility in the channel portion of the first transistor T1 is reduced, a slope of a current curve representing a relationship between the voltage of the gate electrode and the source-drain current of the first transistor T1 may become gentle. Accordingly, because a driving voltage range of the first transistor T1 may be widened, the ease of luminance control may be improved.

As illustrated in FIG. 5, the first transistor T1 may be an N-type MOSFET. In addition, at least some of the second to sixth transistors T2 to T6 may be P-type MOSFETs. As an example, the fifth transistor T5 and the sixth transistor T6 may be P-type MOSFETs, and the second transistor T2, the third transistor T3, and the fourth transistor T4 may be N-type MOSFETs.

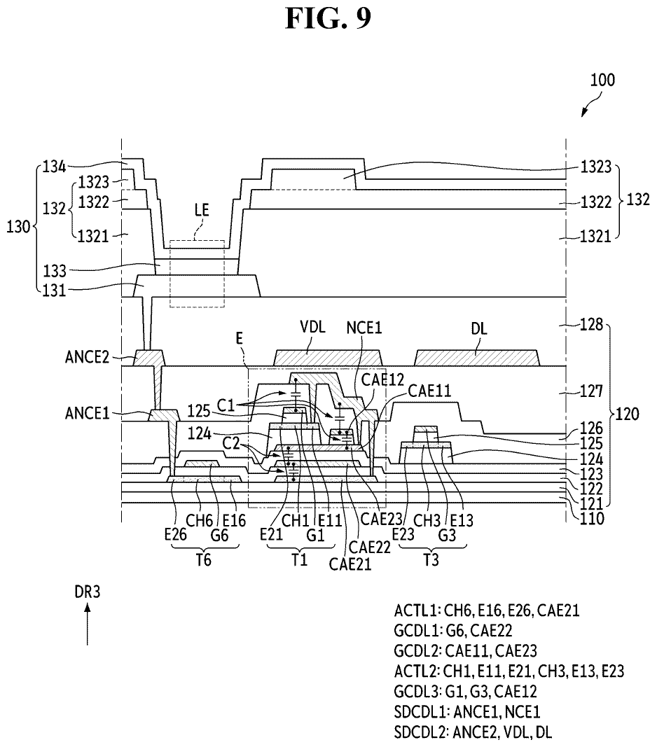

Accordingly, in one or more embodiments, the circuit layer 120 may include a first active layer ACTL1 (see FIG. 9) for providing a P-type MOSFET and a second active layer ACTL2 (see FIG. 9) for providing an N-type MOSFET.

In addition, according to one or more embodiments, in order to improve driving characteristics of the first transistor T1, at least some of the first to sixth transistors T1 to T6 may be oxide transistors including an oxide semiconductor. For example, an active layer of each of at least some of the first to sixth transistors T1 to T6 may include an oxide semiconductor. The remaining transistors excluding the oxide transistors from among the first to sixth transistors T1 to T6 may include a semiconductor material (e.g., amorphous silicon or polysilicon) other than the oxide semiconductor.

For example, the fifth transistor T5 and the sixth transistor T6 may be transistors including a silicon semiconductor, and the first to fourth transistors T1 to T4 may be transistors including an oxide semiconductor.

The oxide semiconductor has high carrier mobility and low leakage current, and accordingly, even if a driving time of the oxide transistor becomes longer, a voltage drop may not significantly occur. For example, the pixel PX including the oxide transistor may be driven at a low frequency, because the luminance and/or color of an image do not significantly change due to a voltage drop even when driven at the low frequency. When at least some of the first to sixth transistors T1 to T6 are formed as the oxide transistors, leakage current of the pixel PX may be reduced or prevented and power consumption may be reduced.

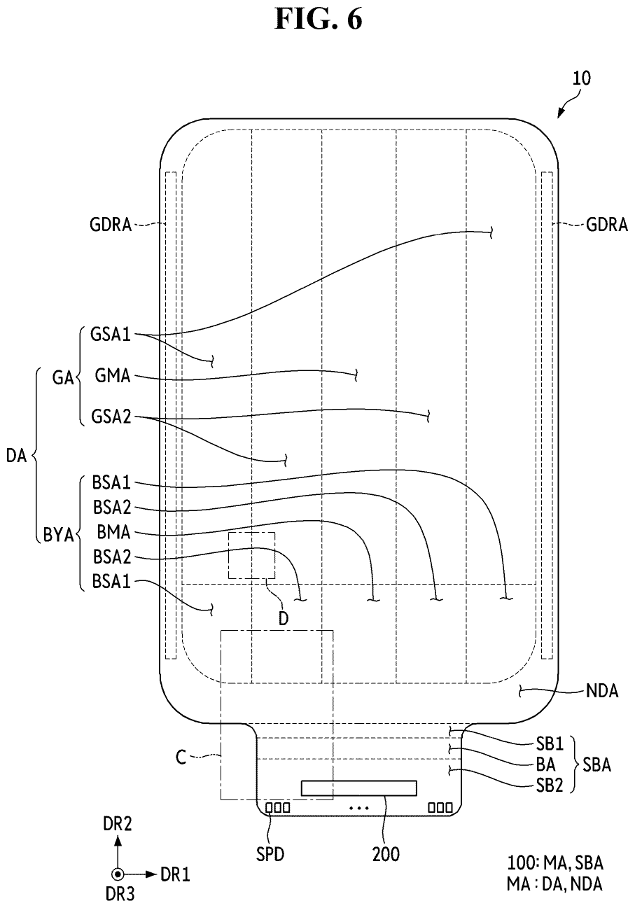

FIG. 6 is a plan view illustrating a display panel and a display driving circuit according to one or more embodiments.

Referring to FIG. 6 in addition to FIG. 5, the display panel 100 may include a main area MA corresponding to the display surface and a sub-area SBA protruding from a portion of one side of the main area MA.

The main area MA includes a display area DA disposed at most of the center and a non-display area NDA disposed at an edge and around (e.g., surrounding) the display area DA.

The display area DA may include a bypass area BYA disposed on one side adjacent to the sub-area SBA, and a general area GA disposed in the remaining area excluding the bypass area BYA.

The bypass area BYA may include a bypass middle area BMA disposed at the center in the first direction DR1, a first bypass side area BSA1 disposed parallel to the bypass middle area BMA in the first direction DR1 and in contact with the non-display area NDA, and a second bypass side area BSA2 disposed between the bypass middle area BMA and the first bypass side area BSA1.

In one or more embodiments, the first bypass side area BSA1 may be disposed on one side and the other side of the bypass middle area BMA in the first direction DR1, respectively. The second bypass side area BSA2 may be disposed on one side and the other side of the bypass middle area BMA in the first direction DR1, respectively. That is, the first bypass side area BSA1 and the second bypass side area BSA2 may be disposed between each side of the bypass middle area BMA in the first direction DR1 and the non-display area NDA.

The first bypass side area BSA1 may be disposed to be adjacent to a bent edge of the display panel 100 compared to the bypass middle area BMA and the second bypass side area BSA2.

The general area GA may include a general middle area GMA connected to the bypass middle area BMA of the bypass area BYA in the second direction DR2, a first general side area GSA1 connected to the first bypass side area BSA1 of the bypass area BYA in the second direction DR2, and a second general side area GSA2 connected to the second bypass side area BSA2 of the bypass area BYA in the second direction DR2.

The non-display area NDA may include a gate driving circuit area GDRA where a gate driving circuit is disposed.

The gate driving circuit area GDRA may face one side of the display area DA extending in the second direction DR2 in the non-display area NDA. However, this is merely an example, and the gate driving circuit area GDRA may be separately disposed in the display area DA rather than the non-display area NDA.

The gate driving circuit in the gate driving circuit area GDRA may sequentially transmit gate signals to gate lines. Here, the gate lines may include a scan write line GWL (see FIG. 5) that transmits a scan write signal GW, a reset control line GRL that transmits a reset control signal GR, a bias control line GBL (see FIG. 5) that transmits a bias control signal GB, a first emission control line ECL1 that transmits a first emission control signal EC1, and a second emission control line ECL2 that transmits a second emission control signal EC2.

The sub-area SBA may include a bending area BA that is deformed into a bent shape, a first sub-area SB1 disposed between one side of the bending area BA and the main area MA, and a second sub-area SB2 connected to the other side of the bending area BA.

When the bending area BA is deformed into the bent shape, the second sub-area SB2 may be disposed below the main area MA and may overlap the main area MA.

The display driving circuit 200 may be disposed in the second sub-area SB2.

Signal pads SPD bonded to the circuit board 300 (see FIG. 3) may be arranged at an edge on one side of the second sub-area SB2.

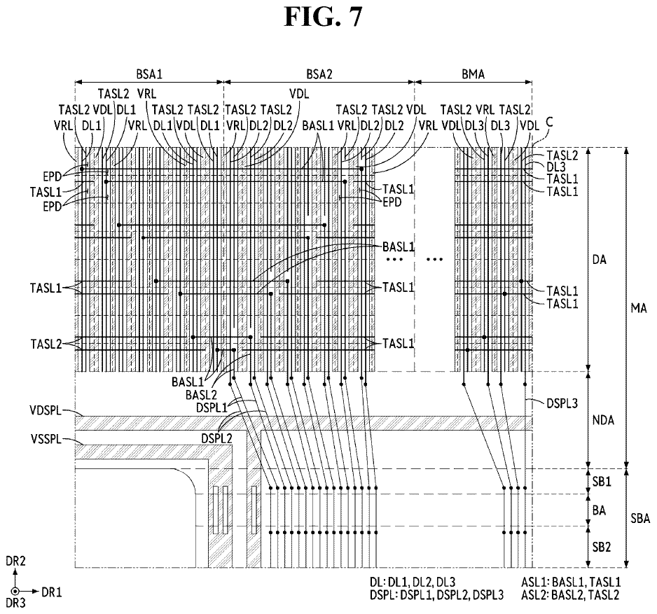

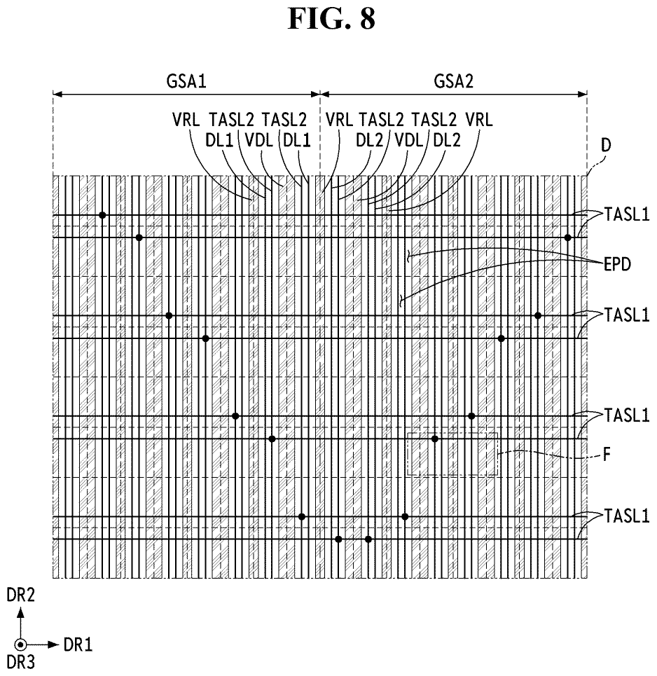

FIG. 7 is a layout view illustrating a circuit layer of portion C of FIG. 6. FIG. 8 is a layout view illustrating a circuit layer of portion D of FIG. 6.

Referring to FIGS. 7 and 8 in addition to FIG. 6, the circuit layer 120 (see FIG. 3) of the display device 10 may include light emitting pixel drivers EPD each electrically connected to the light emitting elements LE (see FIG. 5) of the element layer 130 (see FIG. 3) and arranged parallel to each other along the first direction DR1 and the second direction DR2, data lines DL extending in the second direction DR2 and transmitting the data signals Vdata (see FIG. 5) to the light emitting pixel drivers EPD, first auxiliary lines ASL1 extending in the first direction DR1, and second auxiliary lines ASL2 extending in the second direction DR2 and adjacent to the data lines DL.

The first auxiliary lines ASL1 may include a first bypass auxiliary line BASL1 electrically connected to a first data line DL1 adjacent to the non-display area NDA in the first direction DR1 among the data lines DL, and the remaining first transmission auxiliary lines TASL1 excluding the first bypass auxiliary line BASL1.

The second auxiliary lines ASL2 may include a second bypass auxiliary line BASL2 electrically connected to the first bypass auxiliary line BASL1, and the remaining second transmission auxiliary lines TASL2 excluding the second bypass auxiliary line BASL2.

The second bypass auxiliary line BASL2 may be adjacent to the second data line DL2 that is spaced further from the non-display area NDA than the first data line DL1 in the first direction DR1 from among the data lines DL.

The first data line DL1 may be disposed in the first bypass side area BSA1.

The second data line DL2 and the second bypass auxiliary line BASL2 may be disposed in the second bypass side area BSA2.

The first bypass auxiliary line BASL1 may be disposed in the first bypass side area BSA1 and the second bypass side area BSA2.

As illustrated in FIG. 7, the circuit layer 120 (see FIG. 3) may further include data supply lines DSPL disposed in the non-display area NDA and electrically connected between the display driving circuit 200 (see FIG. 6) and the data lines DL.

The data supply lines DSPL may extend to the bypass middle area BMA and the second bypass side area BSA2.

The data supply lines DSPL may include a first data supply line DSPL1 that transmits a data signal of the first data line DL1, and a second data supply line DSPL2 that transmits a data signal of the second data line DL2.

The first data supply line DSPL1 may extend to the second bypass auxiliary line BASL2 of the second bypass side area BSA2, and may be electrically connected to the first data line DL1 through the second bypass auxiliary line BASL2 and the first bypass auxiliary line BASL1.

The second data supply line DSPL2 may extend to the second bypass side area BSA2 and may be directly electrically connected to the second data line DL2.

In this way, because the first data supply line DSPL1 extends to the second bypass auxiliary line BASL2 of the second bypass side area BSA2, not to the first data line DL1 of the first bypass side area BSA1, an extension length of the first data supply line DSPL1 may be shortened. As a result, a width of an area required for the arrangement of the data supply lines DSPL may be reduced, and thus a width of the non-display area NDA may be reduced.

In addition, because the data supply lines DSPL are not disposed in some areas of the non-display area NDA adjacent to the bent edge of the display panel 100, the width of the non-display area NDA may be further reduced.

The data lines DL may further include a third data line DL3 disposed in the bypass middle area BMA. In addition, the data supply lines DSPL may further include a third data supply line DSPL3 that transmits a data signal of the third data line DL3.

The third data supply line DSPL3 may extend to the bypass middle area BMA and may be directly electrically connected to the third data line DL3.

The first bypass auxiliary line BASL1 may be disposed between the first data line DL1 and the second bypass auxiliary line BASL2.

The second bypass auxiliary line BASL2 may be disposed between the first data supply line DSPL1 and the first bypass auxiliary line BASL1 in the non-display area NDA.

In this way, because the first bypass auxiliary line BASL1 and the second bypass auxiliary line BASL2 are exclusively disposed in the bypass area BYA, and ends of the first bypass auxiliary line BASL1 and ends of the second bypass auxiliary line BASL2 are disposed in the display area DA, visibility of the first bypass auxiliary line BASL1 and the second bypass auxiliary line BASL2 may be improved.

To prevent this, the first auxiliary lines ASL1 may further include the first transmission auxiliary lines TASL1 as well as the first bypass auxiliary line BASL1. In addition, the second auxiliary lines ASL2 may further include the second transmission auxiliary lines TASL2 as well as the second bypass auxiliary line BASL2.

Two of the first transmission auxiliary lines TASL1 may extend from both ends of the first bypass auxiliary line BASL1 to the non-display area NDA.

One of the second transmission auxiliary lines TASL2 may extend from one end of the second bypass auxiliary line BASL2 to the non-display area NDA in a direction away from the sub-area SBA.

Because the second bypass auxiliary line BASL2 is disposed only in the second bypass side area BSA2, each of the first data line DL1 of the first bypass side area BSA1 and the third data line DL3 of the bypass middle area BMA may be entirely adjacent to the second transmission auxiliary lines TASL2.

According to one or more embodiments, each of the first transmission auxiliary lines TASL1 and the second transmission auxiliary lines TASL2 may be electrically connected to one of the first power line VDL (see FIG. 5) that transmits the first power ELVDD (see FIG. 5), the second power line VSL (see FIG. 5) that transmits the second power ELVSS (see FIG. 5), the initialization voltage line VAIL (see FIG. 5) that transmits the initialization voltage VAINT (see FIG. 5), and the reference voltage line VRL (see FIG. 5) that transmits the reference voltage VREF (see FIG. 5). In this way, resistance of a path through which the power or constant voltage is transmitted may be reduced by the first transmission auxiliary lines TASL1 and the second transmission auxiliary lines TASL2.

According to one or more embodiments, the circuit layer 120 (see FIG. 3) may further include a first power supply line VDSPL and a second power supply line VSSPL that are disposed in the non-display area NDA and extend to the sub-area SBA.

The first power supply line VDSPL may transmit the first power ELVDD (see FIG. 5), and the second power supply line VSSPL may transmit the second power ELVSS (see FIG. 5).

The first power supply line VDSPL may be electrically connected to a first power pad for transmitting the first power ELVDD (see FIG. 5) from among the signal pads SPD (see FIG. 6) disposed in the second sub-area SB2.

The second power supply line VSSPL (see FIG. 5) may be electrically connected to a second power pad for transmitting the second power ELVSS (see FIG. 5) from among the signal pads SPD (see FIG. 6) disposed in the second sub-area SB2.

As an example, at least some of the first transmission auxiliary lines TASL1 may be electrically connected to the second power supply line VSSPL.

In addition, at least some of the second transmission auxiliary lines TASL2 may be electrically connected to at least some of the first transmission auxiliary lines TASL1 and to the second power supply line VSSPL.

According to one or more embodiments, the circuit layer 120 (see FIG. 3) may further include first power lines VDL that transmit the first power ELVDD (see FIG. 5) to the light emitting pixel drivers EPD.

The first power lines VDL may extend in the second direction DR2 and be electrically connected to the first power supply line VDSPL.

The first power lines VDL may be disposed between two second auxiliary lines ASL2 that are adjacent to each other in the first direction DR1.

According to one or more embodiments, the circuit layer 120 (see FIG. 3) may further include reference voltage lines VRL that transmit the reference voltage VREF (see FIG. 5) to the light emitting pixel drivers EPD.

The reference voltage lines VRL may extend in the second direction DR2.

The reference voltage lines VRL may be disposed between two data lines DL that are adjacent to each other in the first direction DR1.

As illustrated in FIG. 8, the first transmission auxiliary lines TASL1 of the first auxiliary lines ASL1 and the second transmission auxiliary lines TASL2 of the second auxiliary lines ASL2 may be disposed in the general area GA.

Each of the first transmission auxiliary lines TASL1 may be electrically connected to at least some of the second transmission auxiliary lines TASL2.

As illustrated in FIGS. 7 and 8, according to one or more embodiments, two of the first auxiliary lines ASL1 may be disposed to be adjacent to a boundary between two light emitting pixel drivers EPD that are adjacent to each other in the first direction DR1.

The data lines DL may include a first data line DL1 in the first bypass side area BSA1, and a second data line DL2 in the second bypass side area BSA2.

The second auxiliary lines ASL2 may include the second bypass auxiliary line BASL2 that transmits the data signal of the first data line DL1, and the remaining second transmission auxiliary lines TASL2 excluding the second bypass auxiliary line BASL2.

The second bypass auxiliary line BASL2 may be adjacent to the second data line DL2.

The first auxiliary lines ASL1 may be included in a first source-drain conductive layer SDCDL1.

The first auxiliary lines ASL1 may include the first bypass auxiliary line BASL1 that transmits the data signal of the first data line DL1, and the remaining first transmission auxiliary lines TASL1 excluding the first bypass auxiliary line BASL1.

FIG. 9 is a cross-sectional view illustrating a first transistor, a third transistor, a sixth transistor, a first capacitor, a second capacitor, and a light emitting element of FIG. 5.

Referring to FIG. 9 in addition to FIGS. 3 and 5, the display device 10 according to one or more embodiments may include a substrate 110, a circuit layer 120, and an element layer 130.

According to one or more embodiments, the circuit layer 120 may include a first active layer ACTL1, a first gate insulating layer 122, a first gate conductive layer GCDL1, a second gate insulating layer 123, a second gate conductive layer GCDL2, a first interlayer insulating layer 124, a second active layer ACTL2, a third gate insulating layer 125, a third gate conductive layer GCDL3, a second interlayer insulating layer 126, a first source-drain conductive layer SDCDL1, a first planarization layer 127, a second source-drain conductive layer SDCDL2, and a second planarization layer 128.

According to one or more embodiments, the circuit layer 120 may further include a buffer layer 121. The buffer layer 121 may be disposed on the substrate 110. When the buffer layer 121 is included in the circuit layer 120, the first active layer ACTL1 may be disposed on the buffer layer 121.

As described above with reference to FIG. 5, the light emitting pixel driver EPD may include the first transistor T1 and the two or more transistors T2 to T6 electrically connected to the first transistor T1.

In one or more embodiments, the first to fourth transistors T1, T2, T3, and T4 may be N-type MOSFETs, and the fifth and sixth transistors T5 and T6 may be P-type MOSFETs.

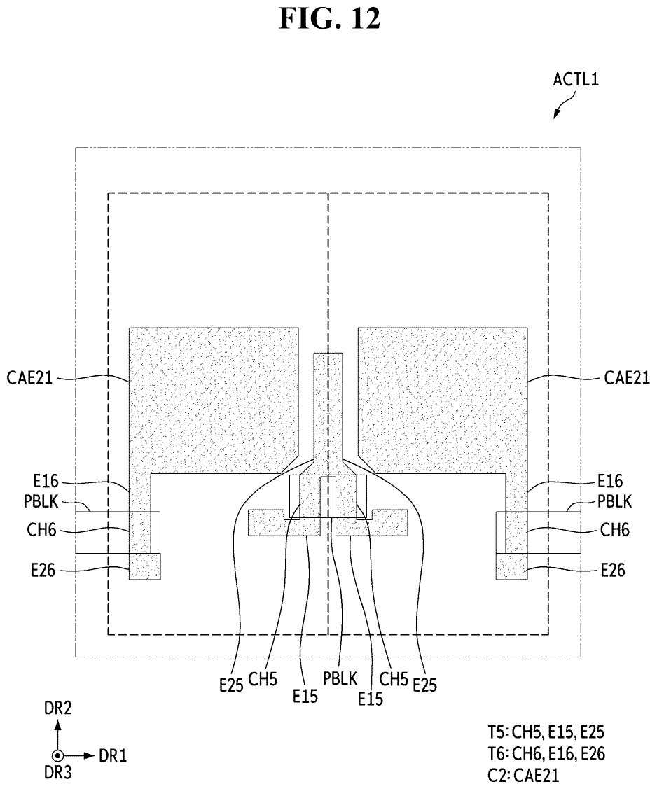

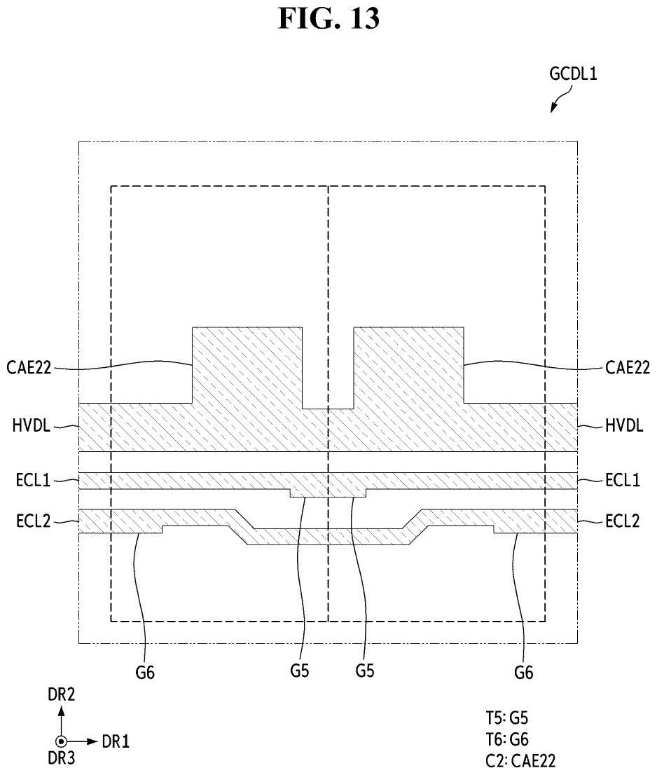

The fifth and sixth transistors T5 and T6 provided as the P-type MOSFET may include channel portions CH5 and CH6 (see FIG. 12), first electrodes E15 and E16 (see FIG. 12), and second electrodes E25 and E26 (see FIG. 12) disposed on the first active layer ACTL1, and gate electrodes G5 and G6 (see FIG. 13) disposed on the first gate conductive layer GCDL1 and overlapping the channel portions CH5 and CH6.

As an example, the first active layer ACTL1 may include a silicon semiconductor material such as polysilicon or amorphous silicon.

That is, as illustrated in FIG. 9, the sixth transistor T6 may include a channel portion CH6 disposed on the first active layer ACTL1, a first electrode E16 disposed on the first active layer ACTL1 and connected to one side of the channel portion CH6, a second electrode E26 disposed on the first active layer ACTL1 and connected to the other side of the channel portion CH6, and a gate electrode G6 disposed on the first gate conductive layer GCDL1 and overlapping the channel portion CH6.

Because the fifth transistor T5 is the same P-type MOSFET as the sixth transistor T6, the redundant description will be omitted below.

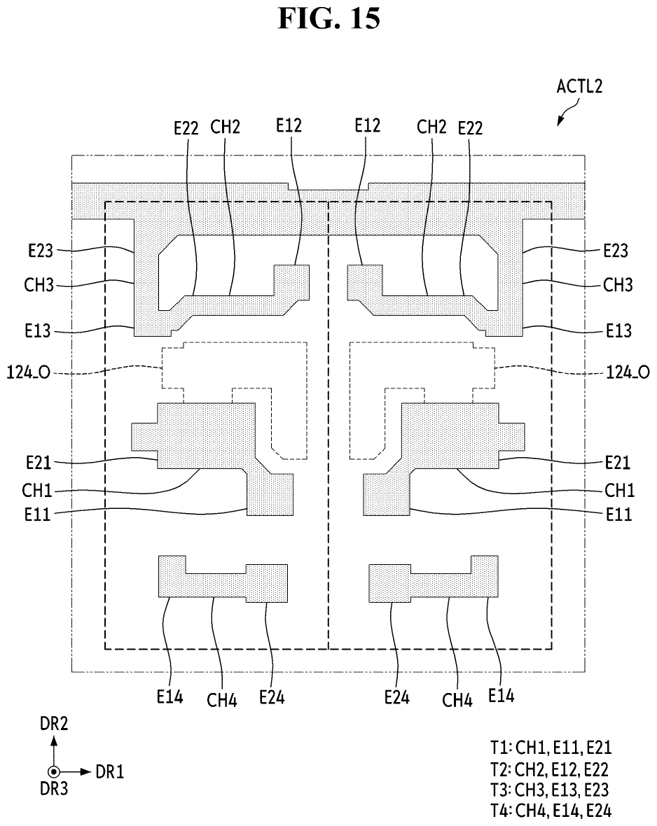

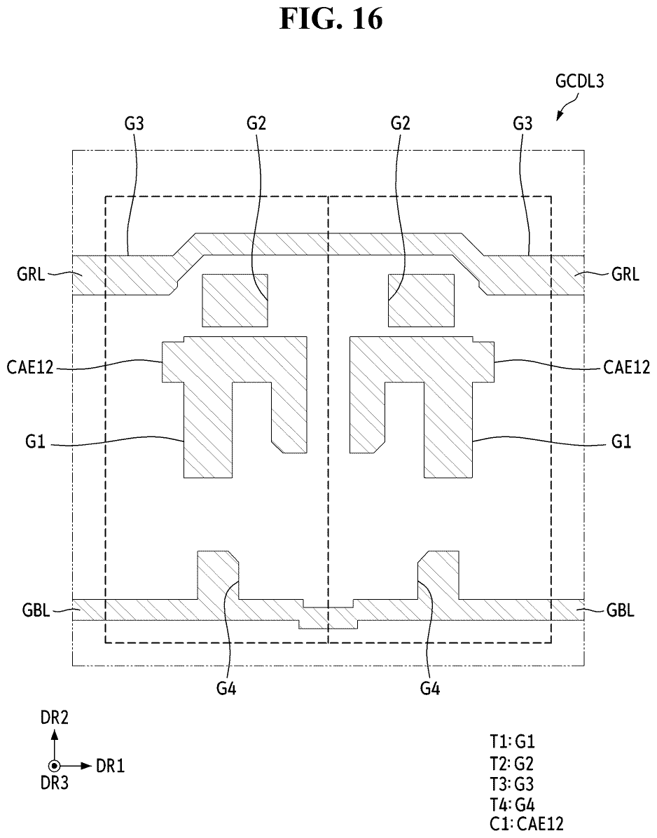

The first to fourth transistors T1, T2, T3, and T4 provided as the N-type MOSFETs may include channel portions CH1, CH2, CH3, and CH4 (see FIG. 15), first electrodes E11, E12, E13, and E14 (see FIG. 15), and second electrodes E21, E22, E23, and E24) (see FIG. 15) disposed on the second active layer ACTL2, and gate electrodes G1, G2, G3, and G4 (see FIG. 16) disposed on the third gate conductive layer GCDL3 and overlapping the channel portions CH1, CH2, CH3, and CH4 (see FIG. 15).

As an example, the second active layer ACTL2 may include an oxide semiconductor material.

That is, as illustrated in FIG. 9, the first transistor T1 may include a channel portion CH1 disposed on the second active layer ACTL2, a first electrode E11 disposed on the second active layer ACTL2 and connected to one side of the channel portion CH1, a second electrode E21 disposed on the second active layer ACTL2 and connected to the other side of the channel portion CH1, and a gate electrode G1 disposed on the third gate conductive layer GCDL3 and overlapping the channel portion CH1.

Similarly, the third transistor T3 may include a channel portion CH3 disposed on the second active layer ACTL2, a first electrode E13 disposed on the second active layer ACTL2 and connected to one side of the channel portion CH3, a second electrode E23 disposed on the second active layer ACTL2 and connected to the other side of the channel portion CH3, and a gate electrode G3 disposed on the third gate conductive layer GCDL3 and overlapping the channel portion CH3.

Because the second transistor T2 and the fourth transistor T4 are the same N-type MOSFETs as the first transistor T1 and the third transistor T3, the redundant descriptions are omitted below.

In one or more embodiments, an upper surface of the channel portion CH1 of the first transistor T1 may face the gate electrode G1. In addition, a lower surface of the channel portion CH1 of the first transistor T1 may face a second capacitor electrode CAE22 that is electrically connected to the second electrode E21 of the first transistor T1. That is, the second capacitor electrode CAE22 may be the gate additional electrode of the first transistor T1.

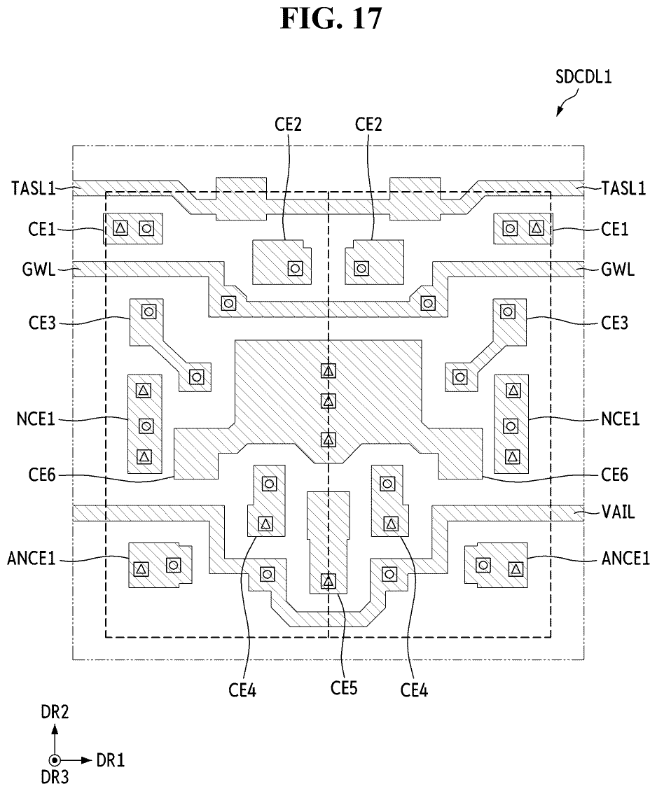

Connection electrodes for connecting the first to sixth transistors T1 to T6 and various lines may be disposed on the first source-drain conductive layer SDCDL1. For example, as illustrated in FIGS. 9 and 17, a first node connection electrode NCE1 and a first anode connection electrode ANCE1 may be disposed on the first source-drain conductive layer SDCDL1.

Power lines such as the first power line VDL and the data line DL may be disposed on the second source-drain conductive layer SDCDL2. A second anode connection electrode ANCE2 connecting the anode electrode 131 and the second electrode E26 of the sixth transistor T6 may be disposed on the second source-drain conductive layer SDCDL2.

The first node connection electrode NCE1 may electrically connect the first electrode E11 of the first transistor T1, and a first capacitor electrode CAE21 of the second capacitor C2 and a third capacitor electrode CAE23 of the second capacitor C2 (or a first capacitor electrode CAE11 of the first capacitor C1).

The first capacitor electrode CAE21 of the second capacitor C2 may be disposed on the first active layer ACTL1. The second capacitor electrode CAE22 of the second capacitor C2 may be disposed on the first gate conductive layer GCDL1. The third capacitor electrode CAE23 of the second capacitor C2 may be disposed on the second gate conductive layer GCDL2.

The first capacitor electrode CAE11 of the first capacitor C1 may be disposed on the second gate conductive layer GCDL2, and may be one electrode physically coupled to the third capacitor electrode CAE23 of the second capacitor C2. The second capacitor electrode CAE12 of the first capacitor C1 may be disposed on the third gate conductive layer GCDL3.

Because, in one or more embodiments, the first capacitor electrode CAE11 of the first capacitor C1 is electrically connected to the second electrode E21 of the first transistor T1 and the second capacitor electrode CAE12 of the first capacitor C1 is electrically connected to the gate electrode G1 of the first transistor T1, the first capacitor C1 may be provided by an area where the first capacitor electrode CAE11 of the first capacitor C1 and the second capacitor electrode CAE12 of the first capacitor C1 overlap each other.

Because the first node connection electrode NCE1 is electrically connected to the second electrode E21 of the first transistor T1 overlaps the second capacitor electrode CAE12 of the first capacitor C1, the first capacitor C1 may also be provided in an area where the second capacitor electrode CAE12 of the first capacitor C1 overlaps the first node connection electrode NCE1.

Because, in one or more embodiments, the first capacitor electrode CAE21 and the third capacitor electrode CAE23 of the second capacitor C2 are electrically connected to the second electrode E21 of the first transistor T1 and the second capacitor electrode CAE22 of the second capacitor C2 is electrically connected to the first power line VDL, the second capacitor C2 may be provided by an area where the second capacitor electrode CAE22 of the second capacitor C2 and the first capacitor electrode CAE21 of the second capacitor C2 overlap each other and an area where the second capacitor electrode CAE22 of the second capacitor C2 and the third capacitor electrode CAE23 of the second capacitor C2 overlap each other.

The second electrode E26 of the sixth transistor T6 may be electrically connected to the anode electrode 131 of the light emitting element LE through the first anode connection electrode ANCE1 and the second anode connection electrode ANCE2.

The first anode connection electrode ANCE1 may be disposed on the first source-drain conductive layer SDCDL1 and may be electrically connected to the second electrode E26 of the sixth transistor T6. The second anode connection electrode ANCE2 may be disposed on the second source-drain conductive layer SDCDL2 and may be electrically connected to the first anode connection electrode ANCE1.

The anode electrode 131 may be disposed on the second planarization layer 128, and may be electrically connected to the second anode connection electrode ANCE2 through a contact hole penetrating through the second planarization layer 128.

The element layer 130 may include light emitting elements LE disposed on the circuit layer 120 and respectively corresponding to the light emitting areas EA.

Each of the light emitting elements LE may include an anode electrode 131 and a cathode electrode 134 that face each other, and a light emitting layer 133 disposed therebetween.

That is, the element layer 130 may include anode electrodes 131 disposed in the light emitting areas EA, a pixel defining layer 132 disposed in the non-light emitting area and covering an edge of the anode electrode 131, light emitting layers 133 disposed on the anode electrodes 131, and a cathode electrode 134 disposed on the light emitting layers 133 and the pixel defining layer 132.

The pixel defining layer 132 may include a first pixel defining layer 1321 disposed on the second planarization layer 128, a second pixel defining layer 1322 disposed on the first pixel defining layer 1321, and a spacer layer 1323 disposed on a portion of the second pixel defining layer 1322.

As an example, the first pixel defining layer 1321 may include a light absorbing insulating material that absorbs light or a light blocking insulating material that blocks light.

Alternatively, each of the light emitting elements LE may further include a first common layer disposed between the anode electrode 131 and the light emitting layer 133, and a second common layer disposed between the light emitting layer 133 and the cathode electrode 134.

The anode electrode 131 may be disposed in each of the light emitting areas EA and may be electrically connected to one light emitting pixel driver EPD of the circuit layer 120. Such an anode electrode 131 may be referred to as a pixel electrode.

The light emitting layer 133 may include an organic light emitting material that converts electron-hole pairs into light.

The cathode electrode 134 may be disposed in the display area DA including the light emitting areas EA. The second power ELVSS may be commonly applied to the cathode electrode 134. Such a cathode electrode 134 may be referred to as a common electrode.

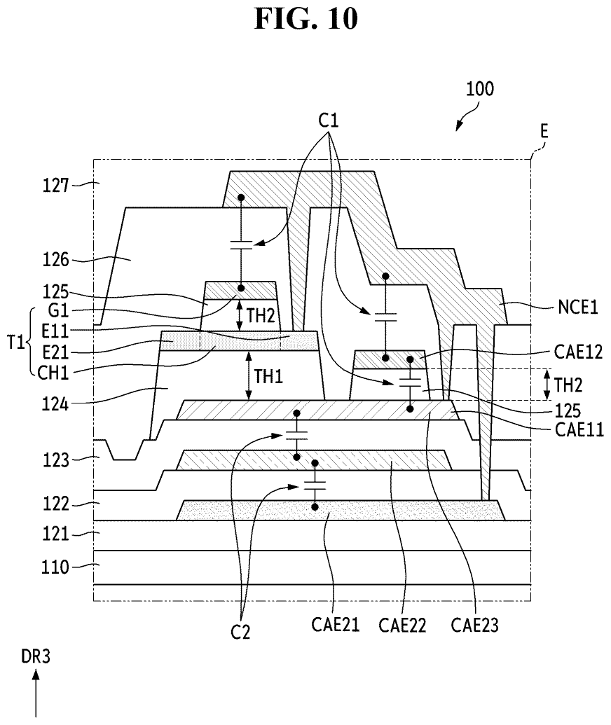

FIG. 10 is an enlarged cross-sectional view of a portion E of FIG. 9.

Referring to FIG. 10 in addition to FIGS. 5 and 9, the second capacitor electrode CAE12 of the first capacitor C1 may be disposed on a different layer from the second capacitor electrode CAE22 of the second capacitor C2. For example, the second capacitor electrode CAE12 of the first capacitor C1 may be disposed on the third gate conductive layer GCDL3, and the second capacitor electrode CAE22 of the second capacitor C2 may be disposed on the first gate conductive layer GCDL1. Accordingly, an area where the second capacitor electrode CAE22 of the second capacitor C2 may be disposed may be expanded as the second capacitor electrode CAE12 of the first capacitor C1 is not disposed. Therefore, the capacitance of the second capacitor C2 may increase.

In addition, because the second capacitor electrode CAE12 of the first capacitor C1 is disposed on the third gate conductive layer GCDL3, the first capacitor C1 may also be formed between the first node connection electrode NCE1 having the same potential as the first capacitor electrode CAE11 of the first capacitor C1 and the second capacitor electrode CAE12 of the first capacitor C1. Therefore, the capacitance of the first capacitor C1 may increase.

In one or more embodiments, the first interlayer insulating layer 124 may be disposed below the first to fourth transistors T1 to T4, and may not be disposed below the second capacitor electrode CAE12 of the first capacitor C1.

Specifically, the first interlayer insulating layer 124 may have a suitable thickness (e.g., a predetermined thickness) or more to prevent interference between the first to fourth transistors T1 to T4 including the oxide semiconductor and the fifth and sixth transistors T5 and T6 including the silicon semiconductor. For example, a thickness TH1 of the first interlayer insulating layer 124 may be approximately 5000 Å, but is not limited thereto.

In one or more embodiments, the third gate insulating layer 125 may have a thickness smaller than that of the first interlayer insulating layer 124 for interaction between the gate electrode and the channel portion in each of the first to fourth transistors T1 to T4. For example, a thickness TH2 of the third gate insulating layer 125 may be approximately 1400 Å, but is not limited thereto.

In the display device 10 according to the present embodiment, the first interlayer insulating layer 124 disposed below the first to fourth transistors T1 to T4 may prevent interference between the first to fourth transistors T1 to T4 including the oxide semiconductor and the fifth and sixth transistors T5 and T6 including the silicon semiconductor.

In addition, the first interlayer insulating layer 124 may not be disposed below the second capacitor electrode CAE12 of the first capacitor C1, and accordingly, the third gate insulating layer 125 having a relatively small thickness may be disposed between the second capacitor electrode CAE12 of the first capacitor C1 and the first capacitor electrode CAE11 of the first capacitor C1. Therefore, the capacitance of the first capacitor C1 may increase.

In one or more embodiments, in a horizontal direction perpendicular to the third direction DR3, the first interlayer insulating layer 124 may overlap the second capacitor electrode CAE12 of the first capacitor C1. That is, the second capacitor electrode CAE12 of the first capacitor C1 may be positioned at a height that overlaps the first interlayer insulating layer 124 in the horizontal direction. For example, a distance between a lower surface of the second capacitor electrode CAE12 of the first capacitor C1 and an upper surface of the substrate 110 may be smaller than a distance between an upper surface of the first interlayer insulating layer 124 and the upper surface of the substrate 110.

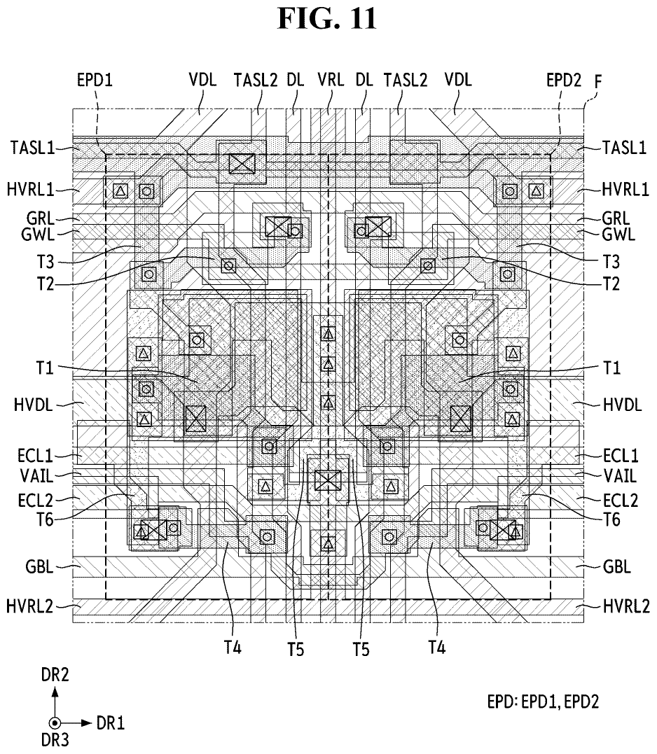

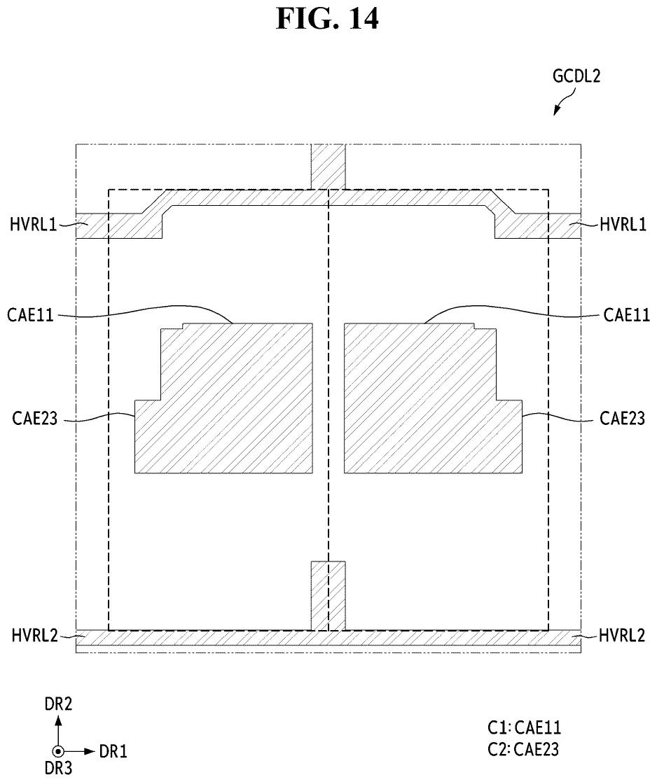

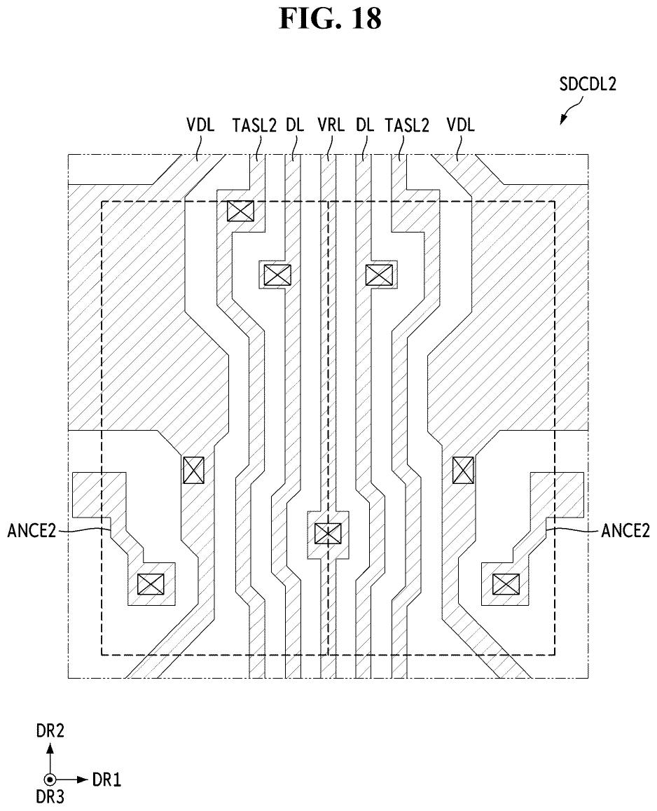

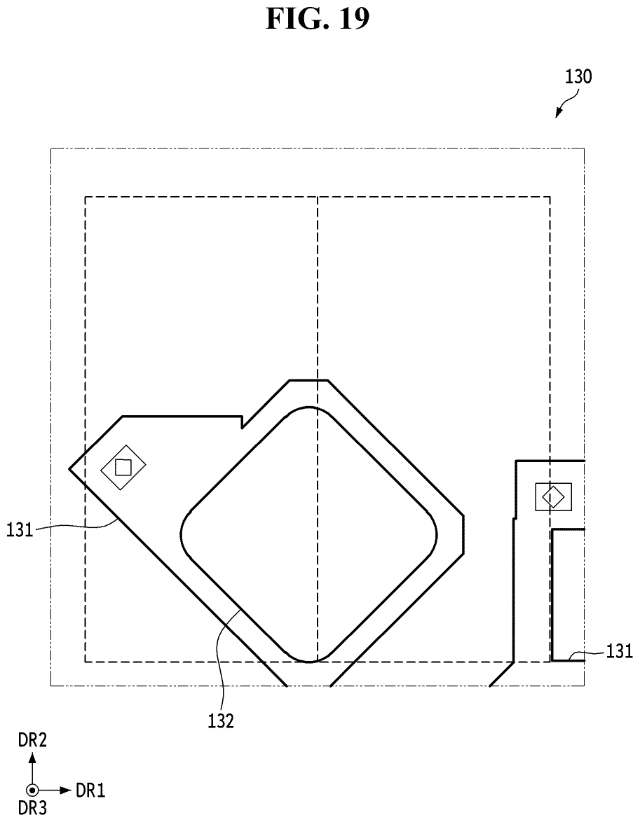

FIG. 11 is a layout view illustrating a circuit layer of a portion F of FIG. 8. FIG. 12 is a layout view illustrating a first active layer and a doped electrode of a circuit layer according to one or more embodiments. FIG. 13 is a layout view illustrating a first gate conductive layer of a circuit layer according to one or more embodiments. FIG. 14 is a layout view illustrating a second gate conductive layer of a circuit layer according to one or more embodiments. FIG. 15 is a layout view illustrating a second active layer of a circuit layer according to one or more embodiments. FIG. 16 is a layout view illustrating a third gate conductive layer of a circuit layer according to one or more embodiments. FIG. 17 is a layout view illustrating a first contact hole group, a second contact hole group, and a first source-drain conductive layer of a circuit layer according to one or more embodiments. FIG. 18 is a layout view illustrating a first via hole group and a second source-drain conductive layer of a circuit layer according to one or more embodiments. FIG. 19 is a layout view illustrating a second via hole group, an anode electrode, and a pixel defining layer of a circuit layer according to one or more embodiments.

Referring to FIGS. 11-19 in addition to FIGS. 3-10, the display panel 100 may include a substrate 110, a circuit layer 120, and an element layer 130.

Because the substrate 110 and the element layer 130 have been described above with reference to FIG. 9, etc., the circuit layer 120 will be described below.

The circuit layer 120 may be disposed on the substrate 110. The circuit layer 120 may include a buffer layer 121, a first active layer ACTL1, a first gate insulating layer 122, a first gate conductive layer GCDL1, a second gate insulating layer 123, a second gate conductive layer GCDL2, a first interlayer insulating layer 124, a second active layer ACTL2, a third gate insulating layer 125, a third gate conductive layer GCDL3, a second interlayer insulating layer 126, a first source-drain conductive layer SDCDL1, a first planarization layer 127, a second source-drain conductive layer SDCDL2, and a second planarization layer 128.

The buffer layer 121 may be disposed on the substrate 110. For example, the buffer layer 121 may be disposed on the entire surface of the substrate 110. The buffer layer 121 may protect the transistors of the circuit layer 120 and the light emitting layer 133 of the element layer 130 from moisture permeating through the substrate 110 that is vulnerable to moisture permeation. The buffer layer 121 may be formed as a plurality of inorganic films that are alternately stacked. For example, the buffer layer 121 may be formed as a multi-film or a single film in which one or more inorganic films of a silicon nitride layer, a silicon oxynitride layer, a silicon oxide layer, a titanium oxide layer, and/or an aluminum oxide layer are alternately stacked.

The first active layer ACTL1 may be disposed on the buffer layer 121. The first active layer ACTL1 may include polycrystalline silicon, single crystal silicon, low-temperature polycrystalline silicon, amorphous silicon, and/or an oxide semiconductor material. For example, as described above with reference to FIG. 5, the first active layer ACTL1 may include a silicon semiconductor material such as polysilicon and/or amorphous silicon.

As illustrated in FIG. 12, the first active layer ACTL1 may include a channel portion CH5, a first electrode E15, and a second electrode E25 of the fifth transistor T5, a channel portion CH6, a first electrode E16, and a second electrode E26 of the sixth transistor T6, and a first capacitor electrode CAE21 of the second capacitor C2.

In one or more embodiments, the first active layer ACTL1 may include a doping prevention area PBLK. The doping prevention area PBLK may be a masking or blocking area to prevent the channel portions CH5 and CH6 from being doped, when a portion of the first active layer ACTL1 is doped to make it electrode (or conductive).

The first gate insulating layer 122 may be disposed on the first active layer ACTL1. The first gate insulating layer 122 may cover the first active layer ACTL1 and the buffer layer 121. The first gate insulating layer 122 may insulate the first active layer ACTL1 and the first gate conductive layer GCDL1 from each other.

The first gate insulating layer 122 may be formed as an inorganic film, for example, a silicon nitride layer, a silicon oxynitride layer, a silicon oxide layer, a titanium oxide layer, and/or an aluminum oxide layer.

The first gate conductive layer GCDL1 may be disposed on the first gate insulating layer 122. The first gate conductive layer GCDL1 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

As illustrated in FIG. 13, the first gate conductive layer GCDL1 may include a gate electrode G5 of the fifth transistor T5, a gate electrode G6 of the sixth transistor T6, a second capacitor electrode CAE22 of the second capacitor C2, a first emission control line ECL1, a second emission control line ECL2, and a first horizontal power line HVDL.

The second gate insulating layer 123 may be disposed on the first gate conductive layer GCDL1. The second gate insulating layer 123 may cover the first gate conductive layer GCDL1 and the first gate insulating layer 122. The second gate insulating layer 123 may insulate the first gate conductive layer GCDL1 and the second gate conductive layer GCDL2 from each other.

The second gate insulating layer 123 may be formed as an inorganic film, for example, a silicon nitride layer, a silicon oxynitride layer, a silicon oxide layer, a titanium oxide layer, and/or an aluminum oxide layer.

The second gate conductive layer GCDL2 may be disposed on the second gate insulating layer 123. The second gate conductive layer GCDL2 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

As illustrated in FIG. 14, the second gate conductive layer GCDL2 may include a first capacitor electrode CAE11 of the first capacitor C1, a third capacitor electrode CAE23 of the second capacitor C2, a first horizontal reference voltage line HVRL1, and a second horizontal reference voltage line HVRL2.

The first interlayer insulating layer 124 may be disposed on the second gate conductive layer GCDL2. The first interlayer insulating layer 124 may cover the second gate conductive layer GCDL2 and the second gate insulating layer 123. The first interlayer insulating layer 124 may insulate the second gate conductive layer GCDL2 and the second active layer ACTL2 from each other.

The first interlayer insulating layer 124 may be formed as an inorganic film, for example, a silicon nitride layer, a silicon oxynitride layer, a silicon oxide layer, a titanium oxide layer, and/or an aluminum oxide layer.

The second active layer ACTL2 may be disposed on the first interlayer insulating layer 124. The second active layer ACTL2 may include polycrystalline silicon, single crystal silicon, low-temperature polycrystalline silicon, amorphous silicon, and/or an oxide semiconductor material. For example, as described above with reference to FIG. 9, the second active layer ACTL2 may include the silicon semiconductor material.

As illustrated in FIG. 15, the second active layer ACTL2 may include a channel portion CH1, a first electrode E11, and a second electrode E21 of the first transistor T1, a channel portion CH2, a first electrode E12, and a second electrode E22 of the second transistor T2, a channel portion CH3, a first electrode E13, and a second electrode E23 of the third transistor T3, and a channel portion CH4, a first electrode E14, and a second electrode E24 of the fourth transistor T4.

The third gate insulating layer 125 may be disposed on the second active layer ACTL2. The third gate insulating layer 125 may cover the second active layer ACTL2. The third gate insulating layer 125 may insulate the second active layer ACTL2 and the third gate conductive layer GCDL3 from each other.

The third gate insulating layer 125 may be formed as an inorganic film, for example, a silicon nitride layer, a silicon oxynitride layer, a silicon oxide layer, a titanium oxide layer, and/or an aluminum oxide layer.

In one or more embodiments, as illustrated in FIG. 9, the third gate insulating layer 125 may be disposed in an area overlapping the channel portion CH1 of the first transistor T1 and the channel portion CH3 of the third transistor T3 in the third direction DR3. In one or more embodiments, the third gate insulating layer 125 may be disposed in an area overlapping the channel portion CH1 of the first transistor T1 and the channel portion CH2 of the second transistor T2 in the third direction DR3.

For example, the third gate insulating layer 125 may not be disposed in an area other than the areas overlapping the channel portions CH1 to CH4 of the first to fourth transistors T1 to T4 in the third direction DR3. Accordingly, the third gate insulating layer 125 may expose the first electrode E11 and the second electrode E21 of the first transistor T1, the first electrode E12 and the second electrode E22 of the second transistor T2, the first electrode E13 and the second electrode E23 of the third transistor T3, and the first electrode E14 and the second electrode E24 of the fourth transistor T4 disposed on the second active layer ACTL2.

The third gate conductive layer GCDL3 may be disposed on the third gate insulating layer 125. The third gate conductive layer GCDL3 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

As illustrated in FIG. 16, the third gate conductive layer GCDL3 may include a gate electrode G1 of the first transistor T1, a gate electrode G2 of the second transistor T2, a gate electrode G3 of the third transistor T3, a gate electrode G4 of the fourth transistor T4, a second capacitor electrode CAE12 of the first capacitor C1, a reset control line GRL, and a bias control line GBL.

The second interlayer insulating layer 126 may be disposed on the third gate conductive layer GCDL3. The second interlayer insulating layer 126 may cover the third gate conductive layer GCDL3, the third gate insulating layer 125, the second active layer ACLT2, the first interlayer insulating layer 124, and the second gate insulating layer 123. The second interlayer insulating layer 126 may insulate the third gate conductive layer GCDL3 and the first source-drain conductive layer SDCDL1 from each other.

The second interlayer insulating layer 126 may be formed as an inorganic film, for example, a silicon nitride layer, a silicon oxynitride layer, a silicon oxide layer, a titanium oxide layer, and/or an aluminum oxide layer.

The first source-drain conductive layer SDCDL1 may be disposed on the second interlayer insulating layer 126. The first source-drain conductive layer SDCDL1 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

As illustrated in FIG. 17, the first source-drain conductive layer SDCDL1 may include a first transmission auxiliary line TASL1, a scan write line GWL, an initialization voltage line VAIL, first to sixth connection electrodes CE1 to CE6, a first node connection electrode NCE1, and a first anode connection electrode ANCE1.

The first planarization layer 127 may be disposed on the first source-drain conductive layer SDCDL1. The first planarization layer 127 may cover the first source-drain conductive layer SDCDL1 and the second interlayer insulating layer 126. The first planarization layer 127 may planarize the steps caused by the layers disposed below the first planarization layer 127. The first planarization layer 127 may insulate the first source-drain conductive layer SDCDL1 and the second source-drain conductive layer SDCDL2 from each other.

The first planarization layer 127 may be formed as an organic film made of an acryl resin, an epoxy resin, a phenolic resin, a polyamide resin, a polyimide resin, and/or the like.

The second source-drain conductive layer SDCDL2 may be disposed on the first planarization layer 127. The second source-drain conductive layer SDCDL2 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

As illustrated in FIG. 18, the second source-drain conductive layer SDCDL2 may include a reference voltage line VRL, a data line DL, a second transmission auxiliary line TASL2, a first power line VDL, and a second anode connection electrode ANCE2.

The second planarization layer 128 may be disposed on the second source-drain conductive layer SDCDL2. The second planarization layer 128 may cover the second source-drain conductive layer SDCDL2 and the first planarization layer 127. The second planarization layer 128 may planarize the steps caused by the layers disposed below the second planarization layer 128. The second planarization layer 128 may insulate the second source-drain conductive layer SDCDL2 and the anode electrode 131.

The second planarization layer 128 may be formed as an organic film made of an acryl resin, an epoxy resin, a phenolic resin, a polyamide resin, a polyimide resin, and/or the like.

The element layer 130 may be disposed on the second planarization layer 128. As illustrated in FIG. 19, the element layer 130 may include an anode electrode 131 and a pixel defining layer 132.

In one or more embodiments, the pixel driver EPD may include a first pixel driver EPD1 and a second pixel driver EPD2. The first pixel driver EPD1 and the second pixel driver EPD2 may be disposed in parallel in the first direction DR1.

In one or more embodiments, as illustrated in FIG. 11, the first pixel driver EPD1 and the second pixel driver EPD2 may be symmetrical to each other with respect to the reference voltage line VRL. The first pixel driver EPD1 and the second pixel driver EPD2 may share some configurations with each other. For example, the first pixel driver EPD1 and the second pixel driver EPD2 may share a second electrode E25 of the fifth transistor T5 disposed on the first active layer ACTL1 (e.g., see FIG. 12), the fifth connection electrode CE5 and the sixth connection electrode CE6 disposed on the first source-drain conductive layer SDCDL1, and a reference voltage line VRL (e.g., see FIG. 17).

In one or more embodiments, the first pixel driver EPD1 and the second pixel driver EPD2 may share data signals or power, voltage, etc. through the first transmission auxiliary line TASL1 and the second transmission auxiliary line TASL2 described below.

Hereinafter, the lines disposed around the pixel driver EPD are described.

The scan write line GWL may extend in the first direction DR1. The scan write line GWL may receive a scan write signal GW from the gate driving circuit and supply the scan write signal GW to the pixel driver EPD. For example, as illustrated in FIGS. 16 and 17, the scan write line GWL may be connected to the gate electrode G2 of the second transistor T2 through a contact hole of a first contact hole group, and may supply the scan write signal GW to the pixel driver EPD through the second gate electrode GE2 of the second transistor T2.

The reset control line GRL may extend in the first direction DR1. The reset control line GRL may receive a reset control signal GR from the gate driving circuit and supply the reset control signal GR to the pixel driver EPD. For example, as illustrated in FIG. 16, the reset control line GRL may be integral with the gate electrode G3 of the third transistor T3, and may supply the reset control signal GR to the pixel driver EPD through the gate electrode G3 of the third transistor T3.

The bias control line GBL may extend in the first direction DR1. The bias control line GBL may receive a bias control signal GB from the gate driving circuit and supply the bias control signal GB to the pixel driver EPD. For example, as illustrated in FIG. 16, the bias control line GBL may be integral with the gate electrode G4 of the fourth transistor T4, and may supply the bias control signal GB to the pixel driver EPD through the gate electrode G4 of the fourth transistor T4.

The first emission control line ECL1 may extend in the first direction DR1. The first emission control line ECL1 may receive a first emission control signal EC1 from the gate driving circuit and supply the first emission control signal EC1 to the pixel driver EPD. For example, as illustrated in FIG. 13, the first emission control line ECL1 may be integral with the gate electrode G5 of the fifth transistor T5, and may supply the first emission control signal EC1 to the pixel driver EPD through the gate electrode G5 of the fifth transistor T5.

The second emission control line ECL2 may extend in the first direction DR1. The second emission control line ECL2 may receive a second emission control signal EC2 from the gate driving circuit and supply the second emission control signal EC2 to the pixel driver EPD. For example, as illustrated in FIG. 13, the second emission control line ECL2 may be integral with the gate electrode G6 of the sixth transistor T6, and may supply the second emission control signal EC2 to the pixel driver EPD through the gate electrode G6 of the sixth transistor T6.

The first horizontal power line HVDL may extend in the first direction DR1. As illustrated in FIGS. 12, 13, 17, and 18 the first horizontal power line HVDL may be connected to the first power line VDL through the sixth connection electrode CE6. The first horizontal power line HVDL may receive the first power ELVDD from the first power line VDL. The first horizontal power line HVDL may be integral with the second capacitor electrode CAE22 of the second capacitor C2 and may supply the first power ELVDD to the second capacitor electrode CAE22 of the second capacitor C2.

The first horizontal reference voltage line HVRL1 and the second horizontal reference voltage line HVRL2 may extend in the first direction DR1. As illustrated in FIGS. 14, 15, 17, and 18 the first horizontal reference voltage line HVRL1 and the second horizontal reference voltage line HVRL2 may be connected to the reference voltage line VRL through the fifth connection electrode CE5. The first horizontal reference voltage line HVRL1 and the second horizontal reference voltage line HVRL2 may be connected to the second electrode E23 of the third transistor T3 through the first connection electrode CE1, and may supply the reference voltage VREF to the second electrode E23 of the third transistor T3.

The first transmission auxiliary line TASL1 may extend in the first direction DR1. The first transmission auxiliary line TASL1 may be connected to the second transmission auxiliary line TASL2 through a contact hole of a second contact hole group. The first transmission auxiliary line TASL1 may be connected to one of the data lines DL or power lines to reduce a width of the non-display area NDA or to lower resistance of a path through which power or a constant voltage is transmitted, as described with reference to FIGS. 7 and 8.

The initialization voltage line VAIL may extend in the first direction DR1. The initialization voltage line VAIL may receive an initialization voltage VAINT from the power supply unit and supply the initialization voltage VAINT to the pixel driver EPD. For example, as illustrated in FIGS. 15 and 17, the initialization voltage line VAIL may be connected to the second electrode E24 of the fourth transistor T4 through the contact hole of the first contact hole group, and may supply the initialization voltage VAINT to the pixel driver EPD through the second electrode E24 of the fourth transistor T4.

In one or more embodiments, two or more of the scan write line GWL, the bias control line GBL, the reset control line GRL, the first emission control line ECL1, the second emission control line ECL2, the first horizontal power line HVDL, the first horizontal reference voltage line HVRL1, the second horizontal reference voltage line HVRL2, the first transmission auxiliary line TASL1, and the initialization voltage line VAIL may be disposed to spaced (e.g., spaced apart) from each other in the second direction DR2 within the same layer.

As an example, the first horizontal power line HVDL, the first emission control line ECL1, and the second emission control line ECL2 disposed on the first gate conductive layer GCDL1 may be sequentially disposed in a direction opposite to the second direction DR2. As another example, the first horizontal reference voltage line HVRL1 and the second horizontal reference voltage line HVRL2 disposed on the second gate conductive layer GCDL2 may be sequentially disposed in the direction opposite to the second direction DR2. As still another example, the reset control line GRL and the bias control line GBL disposed on the third gate conductive layer GCDL3 may be sequentially disposed in the direction opposite to the second direction DR2. As still another example, the first transmission auxiliary line TASL1, the scan write line GWL, and the initialization voltage line VAIL may be sequentially disposed in the direction opposite to the second direction DR2.

The data line DL may extend in the second direction DR2. The data line DL may include at least two data lines DL disposed on one side and the other side in the first direction DR1 with respect to the reference voltage line VRL. The data line DL disposed on the other side in the first direction DR1 with respect to the reference voltage line VRL may be connected to the first pixel driver EPD1, and the data line DL disposed on one side in the first direction DR1 with respect to the reference voltage line VRL may be connected to the second pixel driver EPD2.

The data line DL may receive a data signal Vdata from the display driving circuit 200 and supply the data signal Vdata to the pixel driver EPD. For example, as illustrated in FIGS. 15, 17, and 18, the data line DL may be connected to the first electrode E12 of the second transistor T2 through the contact hole of the second contact hole group, the second connection electrode CE2, and the contact hole of the first contact hole group, and may supply the data signal Vdata to the pixel driver EPD through the first electrode E12 of the second transistor T2.

The first power line VDL may extend in the second direction DR2. The first power line VDL may include at least two first power lines VDL disposed on one side and the other side in the first direction DR1 with respect to the reference voltage line VRL. The first power line VDL disposed on the other side in the first direction DR1 with respect to the reference voltage line VRL may be connected to the first pixel driver EPD1, and the first power line VDL disposed on one side in the first direction DR1 with respect to the reference voltage line VRL may be connected to the second pixel driver EPD2.

The first power line VDL may supply the first power ELVDD received from the power supply unit to the pixel driver EPD. For example, as illustrated in FIGS. 12, 17, and 18, the first power line VDL may be connected to the second electrode E25 of the fifth transistor T5 through the contact hole of the second contact hole group, the sixth connection electrode CE6, and the contact hole of the first contact hole group, and may supply the first power ELVDD to the pixel driver EPD through the second electrode E25 of the fifth transistor T5.

In one or more embodiments, the second power line VSL may extend in the second direction DR2. The second power line VSL may supply the second power ELVSS received from the power supply unit to the pixel driver EPD. For example, the second power line VSL may be connected to the cathode electrode 134 and supply the second power ELVSS to the pixel driver EPD through the cathode electrode 134.

The reference voltage line VRL may extend in the second direction DR2. The reference voltage line VRL may be disposed on a boundary between the first pixel driver EPD1 and the second pixel driver EPD2. The first pixel driver EPD1 and the second pixel driver EPD2 may share the reference voltage line VRL.

The reference voltage line VRL may supply the reference voltage VREF received from the power supply unit to the pixel driver EPD. For example, as illustrated in FIGS. 14, 15, 17, and 18, the reference voltage line VRL may be connected to the second electrode E23 of the third transistor T3 through the fifth connection electrode CE5, the second horizontal reference power line VRL2 (or the first horizontal reference power line VRL1), and the first connection electrode CE1, and may supply the reference voltage VREF to the pixel driver EPD through the second electrode E23 of the third transistor T3.

The second transmission auxiliary line TASL2 may extend in the second direction DR2. The second transmission auxiliary line TASL2 may be connected to the first transmission auxiliary line TASL1 through the contact hole of the second contact hole group. The second transmission auxiliary line TASL2 may be connected to one of the data lines DL or power lines to reduce a width of the non-display area NDA or to lower resistance of a path through which power or a constant voltage is transmitted, as described with reference to FIGS. 7 and 8.

As illustrated in FIG. 11, in a plan view, the first power line VDL, the second transmission auxiliary line TASL2, the data line DL, the reference voltage line VRL, the data line DL, the second transmission auxiliary line TASL2, and the first power line VDL may be sequentially disposed along the first direction DR1. The arrangement of the first power line VDL, the second transmission auxiliary line TASL2, and the data line DL may be symmetrical to each other with respect to the reference voltage line VRL.

As the display device 10 according to the present embodiment includes the first auxiliary lines ASL1 (see FIG. 7) and the second auxiliary lines ASL2 (see FIG. 7), such as the first transmission auxiliary line TASL1 and the second transmission auxiliary line TASL2, the size of the non-display area NDA (see FIG. 6) may be reduced, and a high-resolution display device 10 may be implemented by densely disposing the pixels PX (see FIG. 4). In addition, as the first pixel driver EPD1 and the second pixel driver EPD2 share some lines and configurations, such as the reference voltage line VRL, and the pixel circuit is symmetrically disposed left and right, the degree of integration of the display device 10 may be further increased.

Hereinafter, the first to sixth transistors T1 to T6, the first capacitor C1, and the second capacitor C2 of the pixel driver EPD are described.

The pixel driver EPD may include the first transistor T1, the second transistor T2, the third transistor T3, the fourth transistor T4, the fifth transistor T5, the sixth transistor T6, the first capacitor C1, and the second capacitor C2.

The first to sixth transistors T1 to T6 may each include channel portions CH1 to CH6, first electrodes E11 to E16, second electrodes E21 to E26, and gate electrodes G1 to G6.

The channel portion CH1 of the first transistor T1 may be disposed on the second active layer ACTL2 and may overlap the gate electrode G1 of the first transistor T1.

The gate electrode G1 of the first transistor T1 may be disposed on the third gate conductive layer GCDL3. The gate electrode G1 of the first transistor T1 may be connected to the second capacitor electrode CAE12 of the first capacitor C1. For example, the first gate electrode G1 of the first transistor T1 may be an integral electrode with the second capacitor electrode CAE12 of the first capacitor C1. The gate electrode G1 of the first transistor T1 may be electrically connected to the second electrode E22 of the second transistor T2 through the second capacitor electrode CAE12 of the first capacitor C1 and the third connection electrode CE3.

The first electrode E11 and the second electrode E21 of the first transistor T1 may be disposed on the second active layer ACTL2. The first electrode E11 and the second electrode E21 of the first transistor T1 may be formed by heat-treating a portion of the channel portion CH1 to make it conductive. The first electrode E11 and the second electrode E21 of the first transistor T1 may be conductive as an N-type semiconductor, but are not limited thereto.

The first electrode E11 of the first transistor T1 may be connected to the first electrode E15 of the fifth transistor T5. The first electrode E11 of the first transistor T1 may be connected to the first electrode E15 of the fifth transistor T5 through the fourth connection electrode CE4. The first electrode E11 of the first transistor T1 may receive the first power ELVDD from the first power line VDL through the fifth transistor T5 and the sixth connection electrode CE6.

In one or more embodiments, the second electrode E21 of the first transistor T1 may be connected to the first capacitor electrode CAE11 of the first capacitor C1, the first capacitor electrode CAE21 of the second capacitor C2, and the third capacitor electrode CAE23 of the second capacitor C2 through the first node connection electrode NCE1. In one or more embodiments, the second electrode E21 of the first transistor T1 may be electrically connected to the first electrode E16 of the sixth transistor T6 through the first node connection electrode NCE1 and the first capacitor electrode CAE21 of the second capacitor C2.

The channel portion CH2 of the second transistor T2 may be disposed on the second active layer ACTL2 and may overlap the gate electrode G2 of the second transistor T2.

The gate electrode G2 of the second transistor T2 may be disposed on the third gate conductive layer GCDL3. The gate electrode G2 of the second transistor T2 may be connected to the scan write line GWL. The gate electrode G2 of the second transistor T2 may receive the scan write signal GW from the scan write line GWL.

The first electrode E12 and the second electrode E22 of the second transistor T2 may be disposed on the second active layer ACTL2. The first electrode E12 and the second electrode E22 of the second transistor T2 may be formed by heat-treating a portion of the channel portion CH2 to make it conductive. The first electrode E12 and the second electrode E22 of the second transistor T2 may be conductive as an N-type semiconductor, but are not limited thereto.

The first electrode E12 of the second transistor T2 may be connected to the data line DL through the second connection electrode CE2. The first electrode E12 of the second transistor T2 may receive the data signal Vdata from the data line DL.

The second electrode E22 of the second transistor T2 may be connected to the second capacitor electrode CAE12 of the first capacitor C1 through the third connection electrode CE3. The second electrode E22 of the second transistor T2 may be electrically connected to the gate electrode G1 of the first transistor T1 through the third connection electrode CE3 and the second capacitor electrode CAE12 of the first capacitor C1. The second electrode E22 of the second transistor T2 may supply the gate voltage to the first transistor T1 through the third connection electrode CE3 and the second capacitor electrode CAE12 of the first capacitor C1.

The second electrode E22 of the second transistor T2 may be connected to the first electrode E13 of the third transistor T3. The second electrode E22 of the second transistor T2 may be an integral electrode with the first electrode E13 of the third transistor T3.

The channel portion CH3 of the third transistor T3 may be disposed on the second active layer ACTL2 and may overlap the gate electrode G3 of the third transistor T3.

The gate electrode G3 of the third transistor T3 may be disposed on the third gate conductive layer GCDL3. The gate electrode G3 of the third transistor T3 may be connected to the reset control line GRL. The gate electrode G3 of the third transistor T3 may receive the reset control signal GR from the reset control line GRL.

The first electrode E13 and the second electrode E23 of the third transistor T3 may be disposed on the second active layer ACTL2. The first electrode E13 and the second electrode E23 of the third transistor T3 may be formed by heat-treating a portion of the channel portion CH3 to make it conductive. The first electrode E13 and the second electrode E23 of the third transistor T3 may be conductive as an N-type semiconductor, but are not limited thereto.

The first electrode E13 of the third transistor T3 may be connected to the second electrode E22 of the second transistor T2. The first electrode E13 of the third transistor T3 may be an integral electrode with the second electrode E22 of the second transistor T2. The first electrode E13 of the third transistor T3 may be connected to the second capacitor electrode CAE12 of the first capacitor C1 through the third connection electrode CE3.

The second electrode E23 of the third transistor T3 may be connected to the first horizontal reference voltage line HVRL1 through the first connection electrode CE1. The second electrode E23 of the third transistor T3 may receive the reference voltage VREF from the first horizontal reference voltage line HVRL1 through the first connection electrode CE1 and the first horizontal reference voltage line HVRL1.

The channel portion CH4 of the fourth transistor T4 may be disposed on the second active layer ACTL2 and may overlap the gate electrode G4 of the fourth transistor T4.

The gate electrode G4 of the fourth transistor T4 may be disposed on the third gate conductive layer GCDL3. The gate electrode G4 of the fourth transistor T4 may be connected to the bias control line GBL. The gate electrode G4 of the fourth transistor T4 may be an integral electrode with the bias control line GBL. The gate electrode G4 of the fourth transistor T4 may receive the bias control signal GB from the bias control line GBL.

The first electrode E14 and the second electrode E24 of the fourth transistor T4 may be disposed on the second active layer ACTL2. The first electrode E14 and the second electrode E24 of the fourth transistor T4 may be formed by heat-treating a portion of the channel portion CH4 to make it conductive. The first electrode E14 and the second electrode E24 of the fourth transistor T4 may be conductive as an N-type semiconductor, but are not limited thereto.

The first electrode E14 of the fourth transistor T4 may be connected to the second electrode E26 of the sixth transistor T6 through the first anode connection electrode ANCE1. The first electrode E14 of the fourth transistor T4 may be electrically connected to the anode electrode 131 through the first anode connection electrode ANCE1 and the second anode connection electrode ANCE2.

The second electrode E24 of the fourth transistor T4 may be connected to the initialization voltage line VAIL. The second electrode E24 of the fourth transistor T4 may receive the initialization voltage VAINT from the initialization voltage line VAIL.

The channel portion CH5 of the fifth transistor T5 may be disposed on the first active layer ACTL1 and may overlap the gate electrode G5 of the fifth transistor T5.

The gate electrode G5 of the fifth transistor T5 may be disposed on the first gate conductive layer GCDL1. The gate electrode G5 of the fifth transistor T5 may be connected to the first emission control line ECL1. The gate electrode G5 of the fifth transistor T5 may be an integral electrode with the first emission control line ECL1. The gate electrode G5 of the fifth transistor T5 may receive the first emission control signal EC1 from the first emission control line ECL1.

The first electrode E15 and the second electrode E25 of the fifth transistor T5 may be disposed on the first active layer ACTL1. The first electrode E15 and the second electrode E25 of the fifth transistor T5 may be formed by heat-treating a portion of the channel portion CH5 to make it conductive. For example, as illustrated in FIG. 12, the first electrode E15 and the second electrode E25 of the fifth transistor T5 may be formed by conducting a portion of the channel portion CH5 in an area that does not overlap the doping prevention area PBLK. The first electrode E15 and the second electrode E25 of the fifth transistor T5 may be conductive as a P-type semiconductor, but are not limited thereto.

The first electrode E15 of the fifth transistor T5 may be connected to the first electrode E11 of the first transistor T1 through the fourth connection electrode CE4. The first electrode E15 of the fifth transistor T5 may provide the first power ELVDD received from the first power line VDL to the first transistor T1 through the fourth connection electrode CE4.

The second electrode E25 of the fifth transistor T5 may be connected to the first power line VDL through the sixth connection electrode CE6. The second electrode E25 of the fifth transistor T5 may receive the first power ELVDD from the first power line VDL through the sixth connection electrode CE6.

The channel portion CH6 of the sixth transistor T6 may be disposed on the first active layer ACTL1 and may overlap the gate electrode G6 of the sixth transistor T6.

The gate electrode G6 of the sixth transistor T6 may be disposed on the first gate conductive layer GCDL1. The gate electrode G6 of the sixth transistor T6 may be connected to the second emission control line ECL2. The gate electrode G6 of the sixth transistor T6 may be an integral electrode with the second emission control line ECL2. The gate electrode G6 of the sixth transistor T6 may receive the second emission control signal EC2 from the second emission control line ECL2.

The first electrode E16 and the second electrode E26 of the sixth transistor T6 may be disposed on the first active layer ACTL1. The first electrode E16 and the second electrode E26 of the sixth transistor T6 may be formed by heat-treating a portion of the channel portion CH6 to make it conductive. For example, as illustrated in FIG. 12, the first electrode E16 and the second electrode E26 of the sixth transistor T6 may be formed by conducting a portion of the channel portion CH6 in an area that does not overlap the doping prevention area PBLK. The first electrode E16 and the second electrode E26 of the sixth transistor T6 may be conductive as a P-type semiconductor, but are not limited thereto.

The first electrode E16 of the sixth transistor T6 may be connected to the first capacitor electrode CAE21 of the second capacitor C2. The first electrode E16 of the sixth transistor T6 may be an integral electrode with the first capacitor electrode CAE21 of the second capacitor C2. The first electrode E16 of the sixth transistor T6 may be connected to the second electrode E21 of the first transistor T1, the first capacitor electrode CAE11 of the first capacitor C1, and the third capacitor electrode CAE23 of the second capacitor C2 through the first node connection electrode NCE1.

The second electrode E26 of the sixth transistor T6 may be electrically connected to the anode electrode 131 of the light emitting element LE through the first anode connection electrode ANCE1 and the second anode connection electrode ANCE2. The second electrode E26 of the sixth transistor T6 may supply the driving current to the light emitting element LE through the anode electrode 131. The second electrode E26 of the sixth transistor T6 may be connected to the first electrode E14 of the fourth transistor T4 through the first anode connection electrode ANCE1.

The first capacitor C1 may include the first capacitor electrode CAE11 and the second capacitor electrode CAE12.

The first capacitor electrode CAE11 of the first capacitor C1 may be disposed on the second gate conductive layer GCDL2. The first capacitor electrode CAE11 of the first capacitor C1 may be connected to the second electrode E21 of the first transistor T1, the first electrode E16 of the sixth transistor T6, and the first capacitor electrode CAE21 of the second capacitor C2 through the first node connection electrode NCE1. The first capacitor electrode CAE11 of the first capacitor C1 may be connected to the third capacitor electrode CAE23 of the second capacitor C2. The first capacitor electrode CAE11 of the first capacitor C1 may be an integral electrode with the third capacitor electrode CAE23 of the second capacitor C2.

The second capacitor electrode CAE12 of the first capacitor C1 may be disposed on the third gate conductive layer GCDL3. The second capacitor electrode CAE12 of the first capacitor C1 may be connected to the gate electrode G1 of the first transistor T1. The second capacitor electrode CAE12 of the first capacitor C1 may be an integral electrode with the gate electrode G1 of the first transistor T1. The second capacitor electrode CAE12 of the first capacitor C1 may be connected to the second electrode E22 of the second transistor T2 and the first electrode E13 of the third transistor T3 through the third connection electrode CE3.

The second capacitor C2 may include the first capacitor electrode CAE21, the second capacitor electrode CAE22, and the third capacitor electrode CAE23.

The first capacitor electrode CAE21 of the second capacitor C2 may be disposed on the first active layer ACTL1. The first capacitor electrode CAE21 of the second capacitor C2 may be connected to the second electrode E21 of the first transistor T1 and the first capacitor electrode CAE11 of the first capacitor C1 through the first node connection electrode NCE1. The first capacitor electrode CAE21 of the second capacitor C2 may be connected to the first electrode E16 of the sixth transistor T6. The first capacitor electrode CAE21 of the second capacitor C2 may be an integral electrode with the first electrode E16 of the sixth transistor T6.

The second capacitor electrode CAE22 of the second capacitor C2 may be disposed on the first gate conductive layer GCDL1. The second capacitor electrode CAE22 of the second capacitor C2 may be connected to the first horizontal power line HVDL. The second capacitor electrode CAE22 of the second capacitor C2 may be an integral electrode with the first horizontal power line HVDL. The second capacitor electrode CAE22 of the second capacitor C2 may be connected to the first power line VDL through the sixth connection electrode CE6.

The third capacitor electrode CAE23 of the second capacitor C2 may be disposed on the second gate conductive layer GCDL2. The third capacitor electrode CAE23 of the second capacitor C2 may be connected to the second electrode E21 of the first transistor T1, the first electrode E16 of the sixth transistor T6, and the first capacitor electrode CAE21 of the second capacitor C2 through the first node connection electrode NCE1. The third capacitor electrode CAE23 of the second capacitor C2 may be connected to the first capacitor electrode CAE11 of the first capacitor C1. The third capacitor electrode CAE23 of the second capacitor C2 may be an integral electrode with the first capacitor electrode CAE11 of the first capacitor C1.

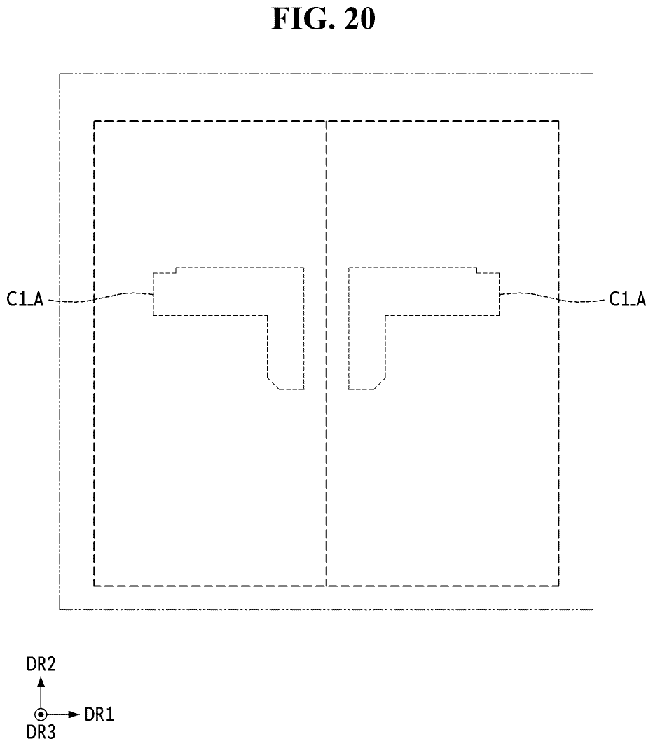

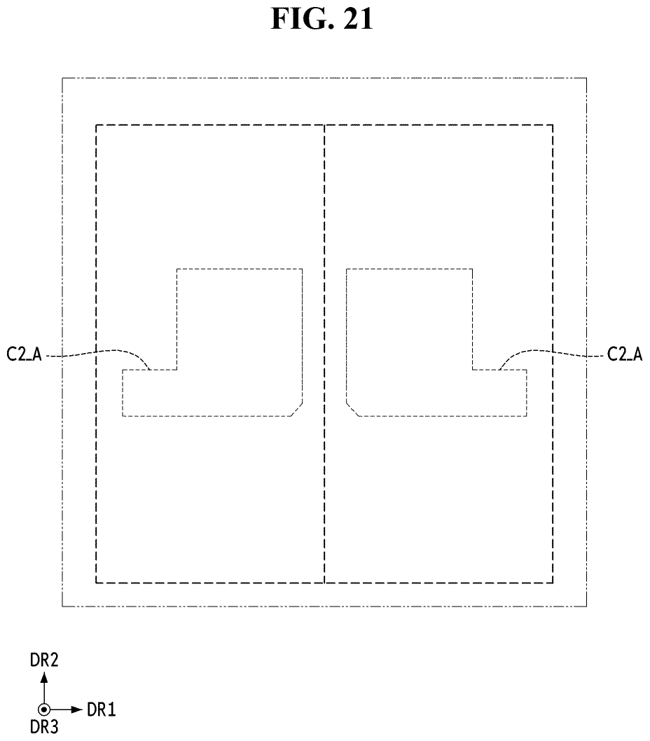

FIG. 20 is a layout view illustrating a first capacitor area. FIG. 21 is a layout view illustrating a second capacitor area.

Referring to FIGS. 20 and 21 in addition to FIGS. 5 and 9-19, the display device 10 according to the present embodiment may include a first capacitor area C1_A and a second capacitor area C2_A. The first capacitor area C1_A may be an area where the first capacitor electrode CAE11 and the second capacitor electrode CAE12 of the first capacitor C1 overlap each other in the third direction DR3. The second capacitor area C2_A may be an area where the first capacitor electrode CAE21 and the second capacitor electrode CAE22 of the second capacitor C2 overlap and an area where the second capacitor electrode CAE22 and the third capacitor electrode CAE23 of the second capacitor C2 overlap.

As described above with reference to FIG. 10, the second capacitor electrode CAE12 of the first capacitor C1 may be disposed on a different layer from the second capacitor electrode CAE22 of the second capacitor C2. For example, the second capacitor electrode CAE12 of the first capacitor C1 may be disposed on the third gate conductive layer GCDL3, and the second capacitor electrode CAE22 of the second capacitor C2 may be disposed on the first gate conductive layer GCDL1. Accordingly, an area where the second capacitor electrode CAE22 of the second capacitor C2 may be disposed may be expanded, as the second capacitor electrode CAE12 of the first capacitor C1 is not disposed on the first gate conductive layer GCDL1, and an area where the second capacitor electrode CAE12 of the first capacitor C1 may be disposed may be expanded, as the second capacitor electrode CAE22 of the second capacitor C2 is not disposed on the third gate conductive layer GCDL3. That is, the areas of the first capacitor area C1_A and the second capacitor area C2_A may each be maximally expanded. Therefore, the capacitances of the first capacitor C1 and the second capacitor C2 may increase.

As illustrated in FIG. 15, the display device 10 according to the present embodiment may include an interlayer insulating layer removal area 124_O. The interlayer insulating layer removal area 124_O may overlap at least a portion of the second capacitor electrode CAE12 of the first capacitor C1 in the third direction DR3. The interlayer insulating layer removal area 124_O may overlap the first capacitor area C1_A in the third direction DR3. The interlayer insulating layer removal area 124_O may not overlap the channel portion CH1, the first electrode E11, and the second electrode E21 of the first transistor T1 in the third direction DR3.

As described above with reference to FIG. 10, the first interlayer insulating layer 124 may be disposed below the second active layer ACTL2, and may not be disposed below the second capacitor electrode CAE12 of the first capacitor C1.

Specifically, the first interlayer insulating layer 124 may be disposed below the second active layer ACTL2 and have a suitable thickness (e.g., a predetermined thickness) or more to prevent interference between the first to fourth transistors T1 to T4 including the oxide semiconductor and the fifth and sixth transistors T5 and T6 including the silicon semiconductor. For example, a thickness TH1 of the first interlayer insulating layer 124 may be approximately 5000 Å, but is not limited thereto.

In one or more embodiments, the third gate insulating layer 125 may have a thickness smaller than that of the first interlayer insulating layer 124 for interaction between the gate electrode and the channel portion in each of the first to fourth transistors T1 to T4. For example, a thickness TH2 of the third gate insulating layer 125 may be approximately 1400 Å, but is not limited thereto.

In the display device 10 according to the present embodiment, the first interlayer insulating layer 124 disposed below the second active layer ACTL2 may prevent interference between the first to fourth transistors T1 to T4 including the oxide semiconductor and the fifth and sixth transistors T5 and T6 including the silicon semiconductor.

In addition, the first interlayer insulating layer 124 may not be disposed below the second capacitor electrode CAE12 of the first capacitor C1, and accordingly, the third gate insulating layer 125 having a relatively small thickness may be disposed between the second capacitor electrode CAE12 of the first capacitor C1 and the first capacitor electrode CAE11 of the first capacitor C1. That is, in the interlayer insulating layer removal area 124_O, the first interlayer insulating layer 124 having a relatively large thickness may not be disposed, and the third gate insulating layer 125 having a relatively small thickness may be disposed. Therefore, as a distance between the first capacitor electrode CAE11 and the second capacitor electrode CAE12 of the first capacitor C1 decreases, the capacitance of the first capacitor C1 may increase.

As the display device 10 according to the present embodiment includes the first auxiliary lines ASL1 (see FIG. 7) and the second auxiliary lines ASL2 (see FIG. 7), such as the first transmission auxiliary line TASL1 and the second transmission auxiliary line TASL2, the size of the non-display area NDA (see FIG. 6) may be reduced, and a high-resolution display device 10 may be implemented by densely disposing the pixels PX (see FIG. 4).

Despite such high degree of integration, the display device 10 according to the present embodiment may increase the capacitance of the capacitor by disposing the second capacitor electrode CAE12 of the first capacitor C1 and the second capacitor electrode CAE22 of the second capacitor C2 on different layers and including the interlayer insulating layer removal area 124_O.

Hereinafter, other embodiments of the display device will be described. In the following embodiments, the same components as those of the above-described embodiment will be denoted by the same reference numerals, and an overlapping description thereof will be omitted or simplified and differences will be mainly described.

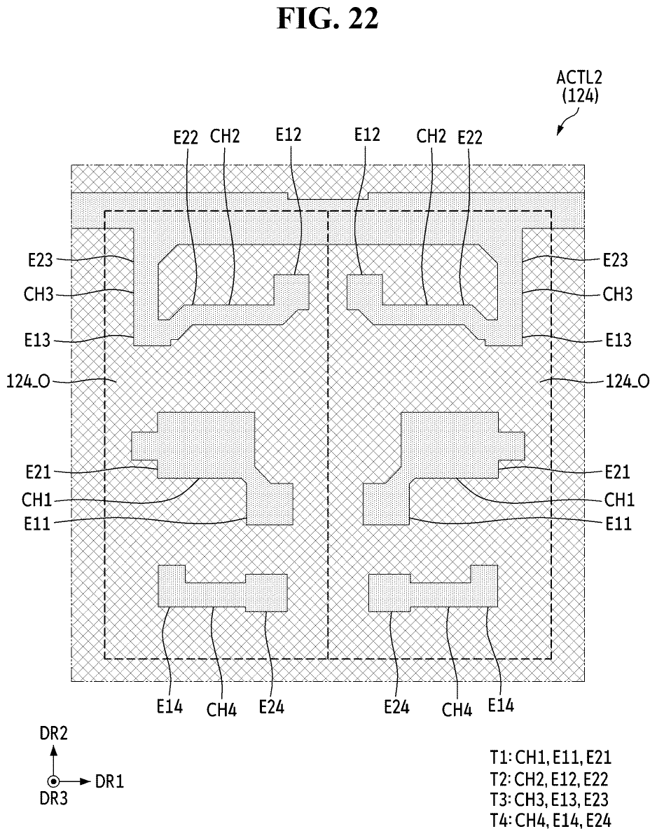

FIG. 22 is a layout view illustrating a first interlayer insulating layer and a second active layer of a circuit layer according to one or more embodiments.

Referring to FIG. 22, a display device 10 according to the present embodiment is different from the display device 10 according to the embodiment described above with reference to FIG. 15 and the like in that the size, shape, and arrangement of the interlayer insulating layer removal area 124_O are different.

More specifically, in the display device 10 according to the present embodiment, the interlayer insulating layer removal area 124_O may be disposed over the entire area other than an area overlapping the second active layer ACTL2.

For example, the first interlayer insulating layer 124 may be disposed only in the area overlapping the second active layer ACTL2, and may be removed from the entire area that does not overlap the second active layer ACTL2.

In this case, the first interlayer insulating layer 124 may be patterned by using a photoresist pattern used to pattern the second active layer ACTL2 as a mask, or the first interlayer insulating layer 124 may also be patterned by using the second active layer ACTL2 as a mask. Accordingly, because the first interlayer insulating layer 124 may be removed without increasing a process mask, process efficiency may be improved.

In one or more embodiments, the size, shape, and arrangement of the interlayer insulating layer removal area 124_O illustrated in FIGS. 15 and 22 are not limited to those illustrated in the drawings. The size, shape, and arrangement of the interlayer insulating layer removal area 124_O may be variously varied. That is, the first interlayer insulating layer 124 may be removed only from the area overlapping the second capacitor electrode CAE12 of the first capacitor C1, as in the embodiment illustrated in FIG. 15, and may be removed from the entire area that does not overlap the second active layer ACTL2, as in the embodiment illustrated in FIG. 22, but is not limited thereto. For example, the first interlayer insulating layer 124 may be removed only from a portion of the area overlapping the second capacitor electrode CAE12 of the first capacitor C1, thereby appropriately adjusting the capacitance of the first capacitor C1.

In concluding the detailed description, those skilled in the art will appreciate that many variations and modifications can be made to the described embodiments without substantially departing from the principles and the scopes of the present disclosure. Therefore, the embodiments of the present disclosure are used in a generic and descriptive sense only and not for purposes of limitation.

What is claimed is:

1. A display device comprising:
a substrate;
a circuit layer on the substrate; and
a light emitting element layer on the circuit layer and comprising light emitting elements,
wherein the circuit layer comprises:
a light emitting pixel driver electrically connected to the light emitting elements;
a first active layer;
a first gate conductive layer on the first active layer;
a second gate conductive layer on the first gate conductive layer;
a second active layer on the second gate conductive layer; and
a third gate conductive layer on the second active layer, and
wherein the light emitting pixel driver comprises:
a first capacitor comprising capacitor electrodes respectively located in the second gate conductive layer and the third gate conductive layer; and
a second capacitor comprising capacitor electrodes respectively located in the first active layer, the first gate conductive layer, and the second gate conductive layer.

2. The display device of claim 1, wherein the circuit layer further comprises an interlayer insulating layer between the second gate conductive layer and the second active layer, and
wherein the interlayer insulating layer exposes at least a portion of an upper surface of the capacitor electrode of the first capacitor, the capacitor electrode of the first capacitor being in the second gate conductive layer.

3. The display device of claim 2, wherein the interlayer insulating layer is not located between the capacitor electrodes of the first capacitor.

4. The display device of claim 2, wherein the interlayer insulating layer does not overlap the capacitor electrode of the first capacitor, the capacitor electrode of the first capacitor being in the third gate conductive layer, in a thickness direction of the substrate.

5. The display device of claim 2, wherein the circuit layer further comprises a gate insulating layer between the second active layer and the third gate conductive layer, and
wherein at least a portion of the gate insulating layer is in contact with the upper surface of the capacitor electrode of the first capacitor, the capacitor electrode of the first capacitor being in the second gate conductive layer.

6. The display device of claim 5, wherein a thickness of the gate insulating layer is smaller than a thickness of the interlayer insulating layer.

7. The display device of claim 2, wherein the light emitting pixel driver further comprises a first transistor on the interlayer insulating layer, and
wherein the interlayer insulating layer is located between the first transistor and the capacitor electrode of the second capacitor, the capacitor electrode of the second capacitor being in the second gate conductive layer.

8. The display device of claim 7, wherein the interlayer insulating layer is located only below the first transistor and is not located below the capacitor electrode of the first capacitor, the capacitor electrode of the first capacitor being in the third gate conductive layer.

9. The display device of claim 8, wherein the interlayer insulating layer was formed by using a pattern of the second active layer as a mask.

10. The display device of claim 1, wherein the first active layer comprises a silicon semiconductor material, and
wherein the second active layer comprises an oxide semiconductor material.

11. The display device of claim 1, wherein the first active layer comprises a p-type semiconductor, and
wherein the second active layer comprises an n-type semiconductor.

12. The display device of claim 1, wherein the above light emitting pixel driver comprises a first light emitting pixel driver and a second light emitting pixel driver that are located in parallel, and
wherein the first light emitting pixel driver and the second light emitting pixel driver have a left-right symmetrical structure with respect to a boundary therebetween.

13. The display device of claim 12, further comprising:
a data line configured to transmit a data signal to the first light emitting pixel driver and the second light emitting pixel driver; and
a transmission auxiliary line electrically connected to the first light emitting pixel driver and the second light emitting pixel driver,
wherein the transmission auxiliary line is configured to be connected to the data line and transmit the data signal.

14. A display device comprising:
a substrate;
a circuit layer on the substrate; and
a light emitting element layer on the circuit layer and comprising light emitting elements,
wherein the circuit layer comprises:
a light emitting pixel driver electrically connected to the light emitting elements and comprising a first transistor, a second transistor, a first capacitor, and a second capacitor; and
an interlayer insulating layer located between the first transistor and the second transistor,
wherein the second capacitor is located below the interlayer insulating layer,
wherein the first capacitor comprises a first capacitor electrode and a second capacitor electrode on the first capacitor electrode, and
wherein a distance between an upper surface of the interlayer insulating layer and an upper surface of the substrate is greater than a distance between a lower surface of the second capacitor electrode of the first capacitor and the upper surface of the substrate.

15. The display device of claim 14, wherein the second capacitor electrode of the first capacitor does not overlap the interlayer insulating layer in a thickness direction of the substrate.

16. The display device of claim 14, wherein the second capacitor electrode of the first capacitor is located above the second capacitor.

17. The display device of claim 14, wherein the interlayer insulating layer overlaps the first transistor in a thickness direction of the substrate.

18. The display device of claim 14, wherein the first transistor comprises an oxide semiconductor, and the second transistor comprises a silicon semiconductor.

19. The display device of claim 14, wherein the circuit layer further comprises a gate insulating layer located between the first capacitor electrode and the second capacitor electrode of the first capacitor, and
wherein the first capacitor electrode is in contact with the gate insulating layer.

20. An electronic device comprising:
a display device configured to display an image;
a processor configured to provide an image driving signal to the display device; and
a power module configured to supply power to the display device and the processor,
the display device comprising:
a substrate;
a circuit layer on the substrate; and
a light emitting element layer on the circuit layer and comprising light emitting elements,
wherein the circuit layer comprises:
a light emitting pixel driver electrically connected to the light emitting elements;
a first active layer;
a first gate conductive layer on the first active layer;
a second gate conductive layer on the first gate conductive layer;
a second active layer on the second gate conductive layer; and
a third gate conductive layer on the second active layer, and
wherein the light emitting pixel driver comprises:
a first capacitor comprising capacitor electrodes respectively located in the second gate conductive layer and the third gate conductive layer; and
a second capacitor comprising capacitor electrodes respectively located in the first active layer, the first gate conductive layer, and the second gate conductive layer.
